(19) United States
(12) Patent Application Publication
(10) Pub. No.: US 2012/0268004 A1
(43) Pub. Date: Oct. 25, 2012

(54) ORGANIC ELECTROLUMINESCENT DISPLAY DEVICE

(75) Inventors: Sung-Jin Choi, Yongin-si (KR); Ok-Keun Song, Yongin-si (KR); Young-Mo Koo, Yongin-si (KR); Doohwan Kim, Yongin-si (KR)

(73) Assignee: Samsung Mobile Display Co., Ltd., Yongin-si (KR)

(21) Appl. No.: 13/449,052

(22) Filed: Apr. 17, 2012

(30) Foreign Application Priority Data
Apr. 19, 2011 (KR) 10-2011-0036348
Feb. 2, 2012 (KR) 10-2012-0010937

(51) Int. Cl. H05B 33/14; H05B 33/28; H05B 33/26; H05B 33/22

(52) U.S. Cl. 313/504

(57) ABSTRACT

Organic electroluminescent display (OELD) devices and method of fabricating them, make use of a printed circuit board as a deposition substrate. The OELD device includes a printed circuit board including a first region provided with at least one first through hole and a second region provided with at least one second through hole, the second region surrounding the first region, a second through electrode disposed in the second through hole, a first electrode including a first through electrode and a first conductive layer, the first through electrode being disposed in the first through hole, and the first conductive layer being disposed on the first through electrode and the printed circuit board, and being spaced apart from the second through electrode, an organic electroluminescent layer disposed on the first electrode, and a second electrode disposed on the organic electroluminescent layer and connected to the second through electrode.

### CROSS-REFERENCE TO RELATED APPLICATIONS

This application claims priority to and the benefit of Korean Patent Application Nos. 10-2011-0036348 filed on Apr. 19, 2011 and 10-2012-0010937 filed on Feb. 2, 2012 in the Korean Intellectual Property Office, the entire contents of which are hereby incorporated by reference.

### BACKGROUND

The described technology relates generally to an organic electroluminescent display device. More particularly, it relates to an organic electroluminescent display device using a printed circuit board as a deposition substrate.

### DESCRIPTION OF THE RELATED TECHNOLOGY

An organic electroluminescent display (OELD) device is a display device using self-luminous characteristics of an organic compound therein. The OELD device can have several advantages, such as a low operation voltage, high brightness, wide viewing angle, and a fast response rate, and thus, it has been extensively studied as an advanced display device.

For a large-area OELD device, there may arise several technical difficulties, such as thermal damage to an organic electroluminescent material, degradation of display quality caused by an unintended voltage drop phenomenon, or increase of non-luminescence area caused by complex current supplying paths. The use of a metallic encapsulating or filling material has been suggested to effectively dissipate internal heat of the device, but it has shown to be ineffectual. The use of an auxiliary electrode has been suggested to overcome degradation of display quality, but this may result in an increase of process steps and a decrease of aperture ratio. In addition, a method of using a printed circuit board (PCB) for an encapsulation process has been adopted to reduce a non-luminescence area, but it has also shown to be ineffectual.

### SUMMARY OF CERTAIN INVENTIVE ASPECTS

Embodiments of the inventive concepts provide an organic electroluminescent display device having an increased luminescence area.

Embodiments of the inventive concepts also provide an organic electroluminescent display device with excellent heat-dissipation efficiency and capable of suppressing an unintended voltage drop.

According to certain embodiments, a printed circuit board may be used as a deposition substrate of an organic electroluminescent display device.

In some embodiments, the organic electroluminescent display device may include a printed circuit board including a first region provided with at least one first through hole and a second region provided with at least one second through hole, the second region surrounding the first region, a second through electrode disposed in the second through hole, a first electrode including a first through electrode and a first conductive layer, the first through electrode being disposed in the first through hole, and the first conductive layer being disposed on the first through electrode and the printed circuit board, and being spaced apart from the second through electrode, an organic electroluminescent layer disposed on the first electrode, and a second electrode disposed on the organic electroluminescent layer and connected to the second through electrode.

In other embodiments, the first electrode may further include a second conductive layer disposed below the first through electrode and the printed circuit board. In addition, the device may further include a third conductive layer connected to the second through electrode and disposed along an edge of the printed circuit board. The third conductive layer may be spaced apart from the second conductive layer and have a closed loop shape surrounding the second conductive layer.

In still other embodiments, at least one of the first electrode, the second through electrode and the third conductive layer may include a metal with a high thermal conductivity. The metal with a high thermal conductivity may be copper (Cu) or gold (Au).

In even other embodiments, the first electrode and the second electrode may serve as an anode and a cathode, respectively, and the first electrode may be formed of a material having a higher work function than the second electrode. In other embodiments, the first electrode and the second electrode may serve as a cathode and an anode, respectively, and the first electrode may be formed of a material having lower work function than the second electrode.

In yet other embodiments, the second electrode is formed of a transparent material. The device may further include a reflective layer interposed between the first electrode and the organic electroluminescent layer.

In some embodiments, at least one of the printed circuit board, the first conductive layer, the reflective layer, and the transparent conductive layer can be formed to form a plurality of light extraction patterns, and the light extraction patterns can be configured to reflect a light generated from the organic electroluminescent layer toward the second electrode.

According to other example embodiments of the inventive concepts, an organic electroluminescent display device may include a printed circuit board including a first region provided with at least one first through hole and a second region provided with at least one second through hole, the first and second regions being adjacent to first and second edges of the printed circuit board, respectively, a second through electrode disposed in the second through hole, a first electrode including a first through electrode and a first conductive layer, the first through electrode being disposed in the first through hole, and the first conductive layer being disposed on the first through electrode and the printed circuit board, and being spaced apart from the second through electrode, an organic electroluminescent layer disposed on the first electrode, and a second electrode disposed on the organic electroluminescent layer and connected to the second through electrode.

In some embodiments, the first electrode may further include a second conductive layer disposed below the first through electrode and the printed circuit board. The second conductive layer may extend from the first edge of the printed circuit board to the second edge thereof adjacent to the first edge.

In other embodiments, the device may further include a third conductive layer disposed below the second through electrode and spaced apart from the second conductive layer. The third conductive layer may extend from the second edge of the printed circuit board to the first edge thereof adjacent to the second edge. Each of the second and third conductive layers may include an extension to have an ‘L’-shaped section, and the extensions of the second and third conductive layers may be opposite to each other.

In still other embodiments, the device may further include a fourth conductive layer disposed on the second through electrode. The fourth conductive layer may be spaced apart from the first conductive layer and disposed adjacent to the second edge of the printed circuit board.

In even other embodiments, at least one of the first electrode, the second through electrode, the third conductive layer, and the fourth conductive layer may include a metal with a high thermal conductivity. The metal with a high thermal conductivity is copper (Cu) or gold (Au).

In yet other embodiments, the second electrode is formed of a transparent material. In addition, the device may further include a reflective layer interposed between the first electrode and the organic electroluminescent layer.

In example embodiments, at least one of the printed circuit board, the first conductive layer, the reflective layer, and the transparent conductive layer can be formed to form a plurality of light extraction patterns, and the light extraction patterns can be configured to reflect a light generated from the organic electroluminescent layer toward the second electrode.

### BRIEF DESCRIPTION OF THE DRAWINGS

Certain embodiments will be more clearly understood from the following brief description taken in conjunction with the accompanying drawings. The accompanying drawings represent non-limiting, example embodiments as described herein.

FIGS. 1A and 1B are top and bottom plan views of an embodiment of an organic electroluminescent display device;

FIGS. 2A through 7A are plan views illustrating an embodiment of a method of fabricating an organic electroluminescent display device, and FIGS. 2B through 7B are sectional views taken along dotted lines A-A′ of FIGS. 2A through 7A, respectively;

FIGS. 8A and 8B are top and bottom plan views of an embodiment of an OELD device with an inverted structure;

FIG. 9 is a sectional view taken along a dotted line A-A′ of FIG. 8A;

FIGS. 10A and 10B are top and bottom plan views of another embodiment of an OELD device;

FIGS. 11A through 16A are plan views illustrating another embodiment of a method of fabricating an OELD device, and FIGS. 11B through 16B are sectional views taken along dotted lines A-A′ of FIGS. 11A through 16A, respectively;

FIGS. 17A and 17B are top and bottom plan views of another embodiment of an OELD device with an inverted structure;

FIG. 18 is a sectional view taken along a dotted line A-A′ of FIG. 17A.

FIGS. 19A and 19B are top and bottom plan views of another embodiment of an OELD device;

FIGS. 20A through 25A are plan views illustrating another embodiment of a method of fabricating an OELD device, and FIGS. 20B through 25B are sectional views taken along dotted lines A-A′ of FIGS. 20A through 25A, respectively;

FIGS. 26A and 26B are top and bottom plan views of another embodiment of an OELD device with an inverted structure;

FIG. 27 is a sectional view taken along a dotted line A-A′ of FIG. 26A;

FIGS. 28A through 28C are plan views of modified embodiment of OELD devices with an inverted structure;

FIG. 29A and FIG. 29B are plan and bottom views illustrating another embodiment of an OELD device;

FIG. 30A is a sectional view taken along line A-A′ line of FIG. 29A;

FIG. 30B is a sectional view taken along ling B-B′ line of FIG. 29A;

FIG. 30C is an enlarged view of region H of FIG. 30B;

FIG. 31A is a sectional view illustrating a modified embodiment of the OELD device;

FIG. 31B is an enlarged view of region H′ of FIG. 31A;

FIG. 32A and FIG. 32B are plan and bottom views illustrating another embodiment of an OELD device;

FIG. 33A is a sectional view taken along line A-A′ of FIG. 32A;

FIG. 33B is a sectional view taken along line B-B′ of FIG. 32A;

FIG. 33C is an enlarged view of region I of FIG. 32B;

FIG. 34A is a sectional view illustrating a modified embodiment of the OELD device; and

FIG. 34B is an enlarged view of region H′ of FIG. 34A.

It should be noted that these figures are intended to illustrate the general characteristics of methods, structure and/or materials utilized in certain embodiments and to supplement the written description provided below. These drawings are not, however, to scale and may not precisely reflect the precise structural or performance characteristics of any given embodiment, and should not be interpreted as defining or limiting the range of values or properties encompassed by the embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE RELATED TECHNOLOGY

Certain embodiments of the inventive concepts will now be described more fully with reference to the accompanying drawings. Embodiments of the inventive concepts may, however, be embodied in many different forms and should not be construed as being limited to the embodiments set forth herein; rather, these embodiments are provided so that this disclosure will be thorough and complete, and will fully convey the concept to those of ordinary skill in the art. In the drawings, the thicknesses of layers and regions may be exaggerated for clarity. Like reference numerals in the drawings generally denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a similar fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Certain embodiments of the inventive concepts are described herein with reference to cross-sectional illustrations that are schematic illustrations of of certain embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which certain embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

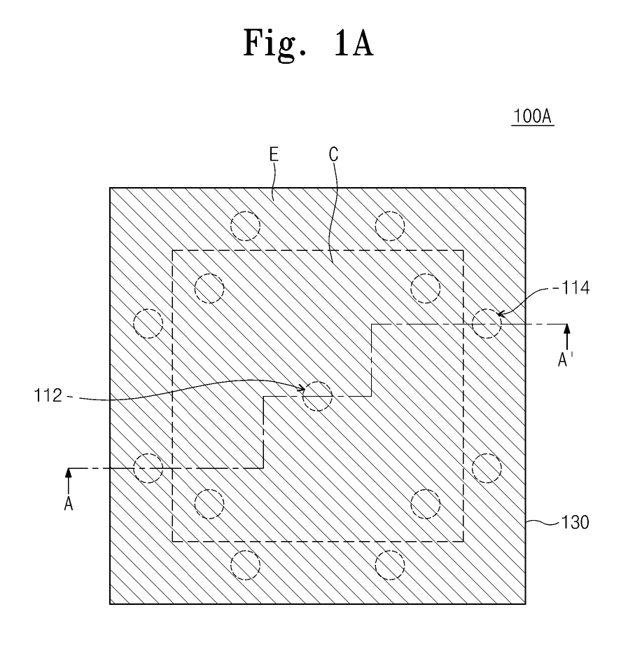

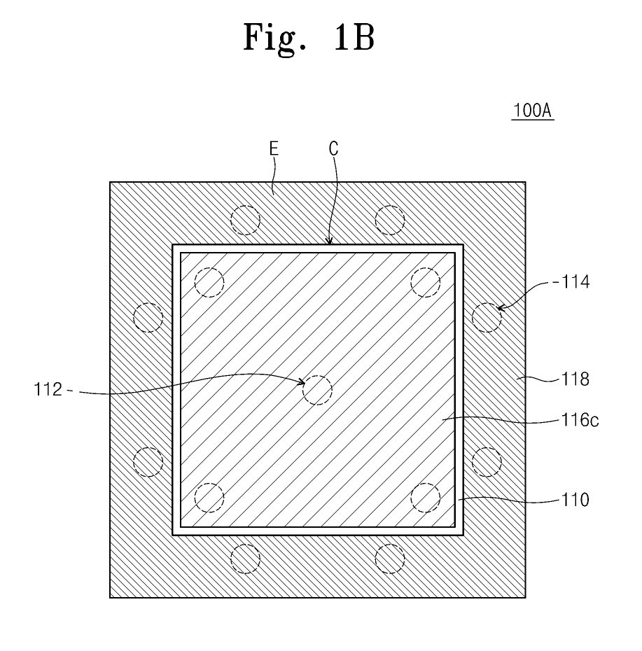

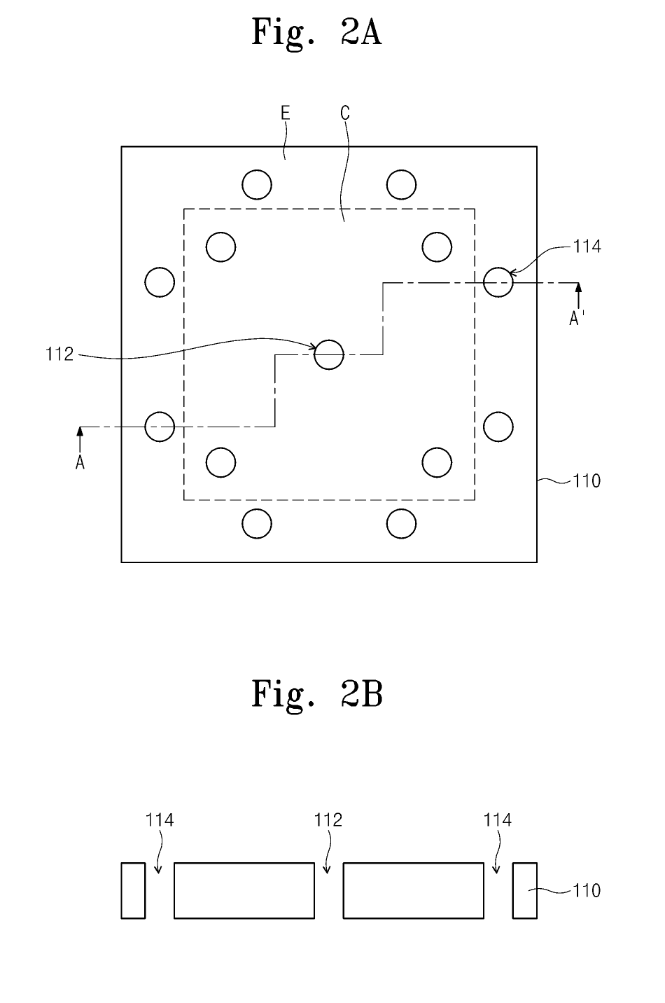

FIGS. 1A and 1B are top and bottom plan views of an embodiment of an organic electroluminescent display device, FIGS. 2A through 7A are plan views illustrating an embodiment of a method of fabricating an organic electroluminescent display device, and FIGS. 2B through 7B are sectional views taken along dotted lines A-A′ of FIGS. 2A through 7A, respectively.

Referring to FIGS. 1A, 1B, 2A and 2B, an organic electroluminescent display (OELD) device 100A may include a printed circuit board (PCB) substrate 110. The PCB substrate 110 may include a first region C including at least one first through hole 112 and a second region E including at least one second through hole 114. The second region E may be provided to surround the first region C. The PCB substrate 110 may be a substrate including a circuit portion, which may be used to operate an organic electroluminescent layer (not shown) of the OELD device 100A. The PCB substrate 110 may include at least one of plastic, metal (such as, for example, copper, aluminum, iron alloy, and the like), glass, or ceramic.

In some embodiments, a plurality of the first through holes 112 may be radially arranged in the first region C. The second region E may include a plurality of side portions surrounding the first region C, and a plurality of the second through holes 114 may be arranged in a row in each of side portions of the second region E. The second through hole 114 may be formed in such a way that an area of a non-luminescence region can be minimized. The first and second through holes 112 and 114 may be formed using a mechanical drilling method or a laser drilling method.

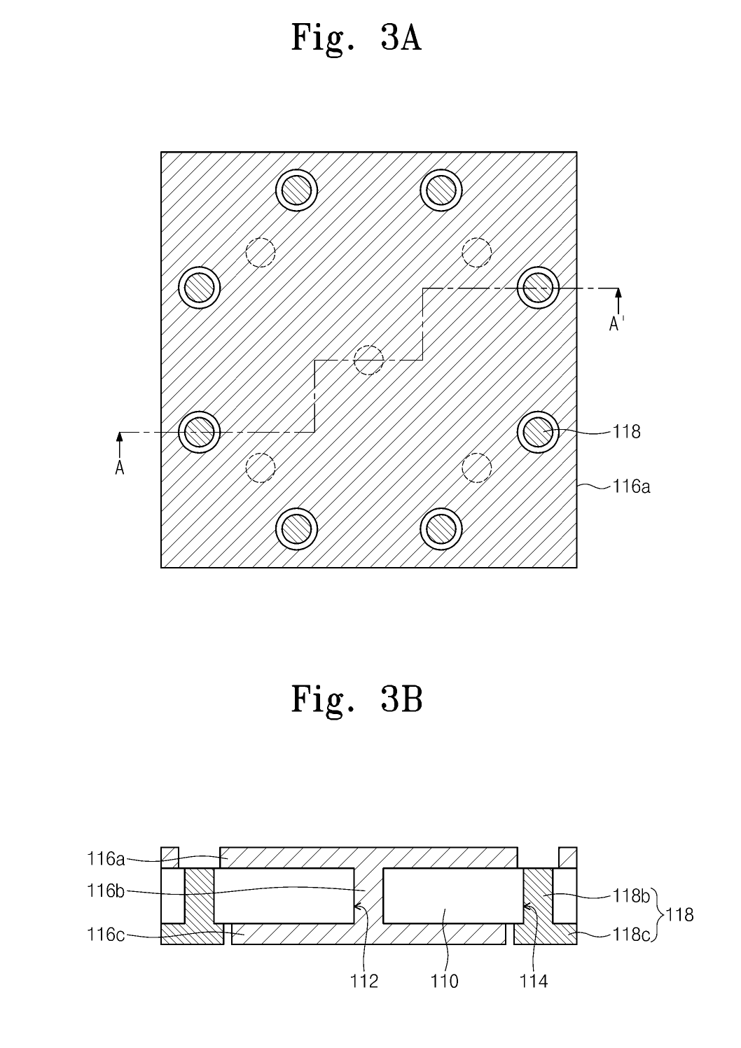

Referring to FIGS. 1A, 1B, 3A and 3B, a first through electrode 116b may be formed in the first through hole 112, and a second through electrode 118b may be formed in the second through hole 114. A first conductive layer 116a may be formed on the first through electrode 116b and the PCB substrate 110 to be spaced apart from the second through electrode 118b. The first conductive layer 116a may expose the second through electrode 118b. A second conductive layer 116c may be formed below the first through electrode 116b and the PCB substrate 110 to be spaced apart from the second through electrode 118b.

A third conductive layer 118c may be formed below the second through electrode 118b and the PCB substrate 110. In some embodiments, the third conductive layer 118c may be formed along the second region E of the PCB substrate 110. The third conductive layer 118c may be spaced apart from the second conductive layer 116c and have a closed loop shape surrounding the second conductive layer 116c. The second through electrode 118b and the third conductive layer 118c may constitute a connection electrode 118.

In some embodiments, the first conductive layer 116a, the first through electrode 116b, the second conductive layer 116c, and the connection electrode 118 may be formed of thick metal layers having high thermal conductivity, thereby reflecting an incident light. In some embodiments, the first conductive layer 116a, the first through electrode 116b, the second conductive layer 116c, and the connection electrode 118 may include at least one of copper (Cu), gold (Au), or alloys thereof.

The first conductive layer 116a, the first through electrode 116b, the second conductive layer 116c, and the connection electrode 118 may be thick enough to achieve low resistance and suppress an unintended voltage drop phenomenon. In some embodiments, the second conductive layer 116c may contribute to improve heat-dissipation efficiency and to suppress an unintended voltage drop phenomenon. Similarly, the third conductive layer 118c may contribute to suppress an unintended voltage drop phenomenon. In other embodiments, the OELD device 100A may not include the second conductive layer 116c and the third conductive layer 118c.

The formation of the first conductive layer 116a, the first through electrode 116b, the second conductive layer 116c, and the connection electrode 118 may include forming a layer using at least one of a plating method, a printing method such as a screen printing technique, a depositing method or any combination thereof, and then patterning the layer.

In some embodiments, the first and second through electrodes 116b and 118b may be formed by filling the first and second through holes 112 and 114 with a metallic paste using a screen printing technique. Thereafter, a layer (not shown) may be formed on and below the PCB substrate 110 using a plating technique, and patterned to form the first, second and third conductive layers 116a, 116c, and 118c.

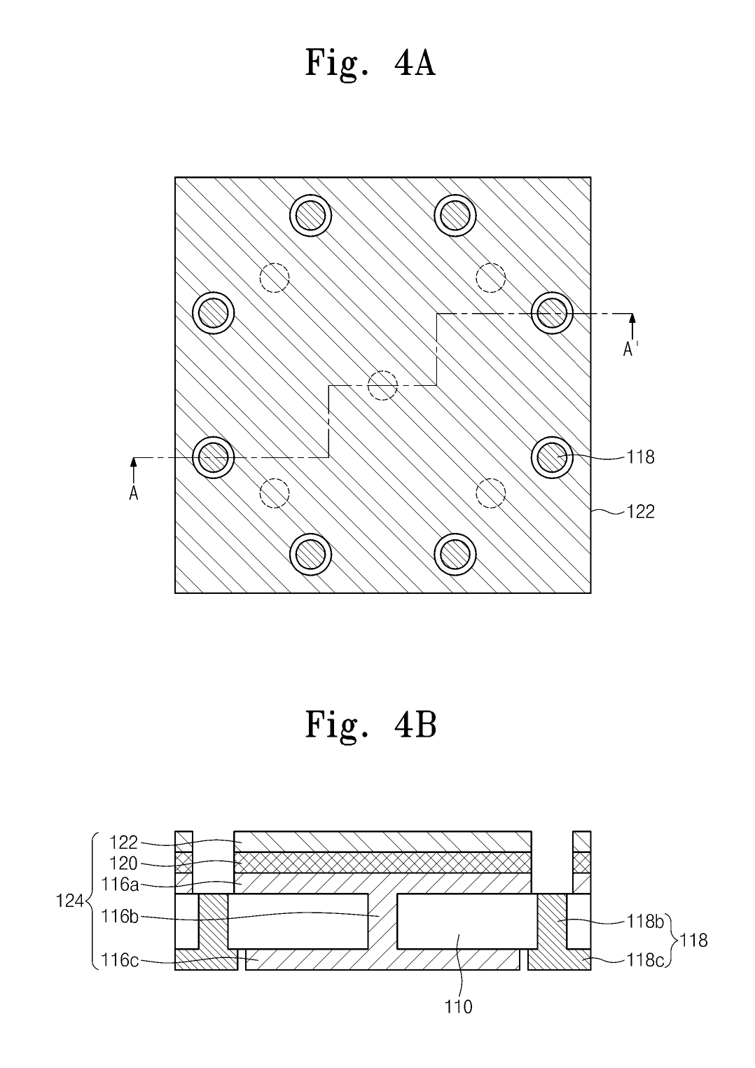

Referring to FIGS. 1A, 1B, 4A and 4B, a reflective layer 120 and a transparent conductive layer 122 may be sequentially formed on the first conductive layer 116a. The reflective layer 120 may be formed of a metallic layer with high conductivity, high thermal conductivity, and high optical reflectance, such as, for example, silver (Ag), nickel (Ni), or alloys thereof. The formation of the reflective layer 120 may include forming a layer (not shown) using a deposition method or a paste method and patterning the layer.

The transparent conductive layer 122 may be formed of one of transparent conductive oxides, such as indium-tin-oxide (ITO), indium-zinc-oxide (IZO), aluminum zinc oxide (AZO), gallium doped zinc oxide (GZO), zinc tin oxide (ZTO), gallium tin oxide (GTO), and fluorine doped tin oxide (FTO). The formation of the transparent conductive layer 122 may include forming a layer (not shown) using a deposition method and patterning the layer.

According to example embodiments, the first conductive layer 116a, the first through electrode 116b, the second conductive layer 116c, the reflective layer 120, and the transparent conductive layer 122 may constitute a first electrode 124.

In embodiments where the first electrode 124 includes the first conductive layer 116a and the reflective layer 120, the OELD device 100A can exhibit improved heat dissipation and reflectance characteristics. Accordingly, it is possible to increase the life time and efficiency of the OELD device 100A. In embodiments where the first electrode 124 includes the transparent conductive layer 122, the OELD device 100A can exhibit improved uniformity of brightness without the need of an additional auxiliary electrode. The reflective layer 120 and the transparent conductive layer 122 may contribute to improve properties of the OELD device 100A, such as heat dissipation, reflectance and brightness uniformity, but example embodiments may not be limited thereto. In other embodiments, the OELD device 100A may be configured not to include the reflective layer 120 and the transparent conductive layer 122.

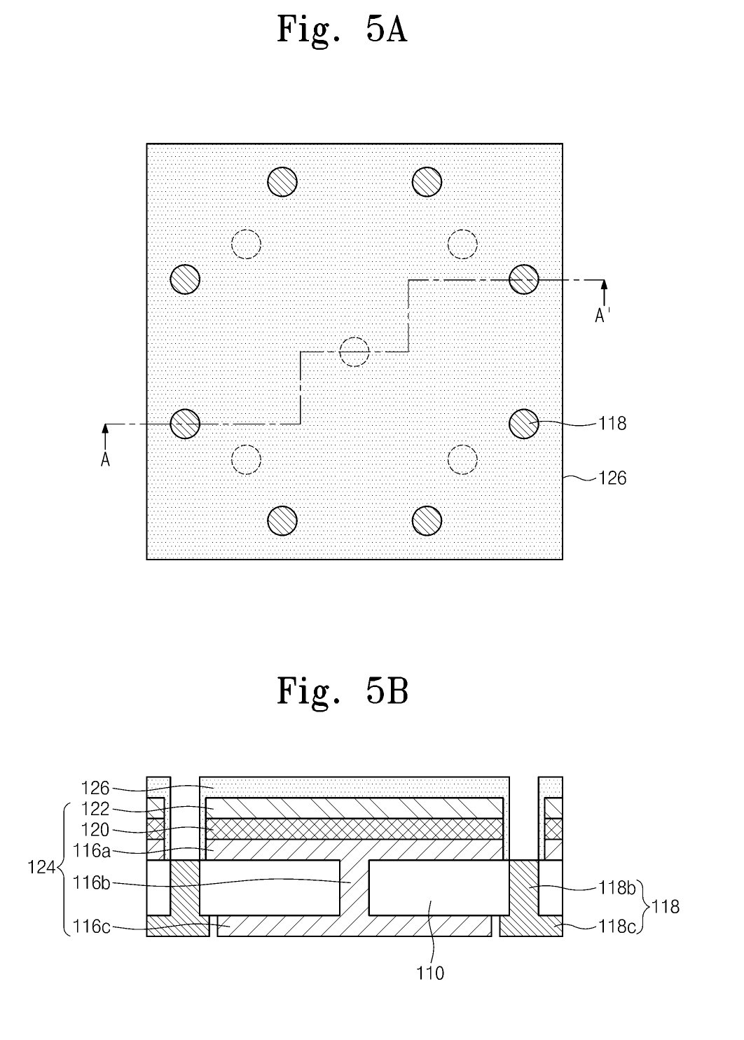

Referring to FIGS. 1A, 1B, 5A and 5B, an organic electroluminescent layer 126 may be formed on the first electrode 124. The organic electroluminescent layer 126 may be configured to emit outward energy generated by the recombination of holes and electrons in the form of light. A light may be generated from the organic electroluminescent layer 126. The organic electroluminescent layer 126 may be formed of an organic electroluminescent material capable of generating one of red, green, blue and white lights. In some embodiments, the organic electroluminescent material may include at least one of polyfluorene derivative, polyparaphenylenevinylene derivative, polyphenylene derivative, polyvinylcarbazole derivative, polythiophene derivative, anthracene derivative, butadiene derivative, tetracene derivative, distyrylarylene derivative, benzazole derivative, or carbazole derivative. In other embodiments, the organic electroluminescent layer 126 may be formed by doping the organic electroluminescent material with dopants, and thereby improving luminous efficiency of the OELD device 100A. The dopant may be at least one of xanthene, perylene, cumarine, rhodamine, rubrene, dicyanomethylenepyran, thiopyran, thiapyrilium, periflanthene derivative, indenoperylene derivative, carbostyryl, Nile red, or quinacridone.

In some embodiments, the organic electroluminescent layer 126 may further include an auxiliary layer (not shown) to improve luminous efficiency of the OELD device 100A. The auxiliary layer may include a hole injecting layer, a hole transfer layer, an electron transfer layer, or an electron injecting layer.

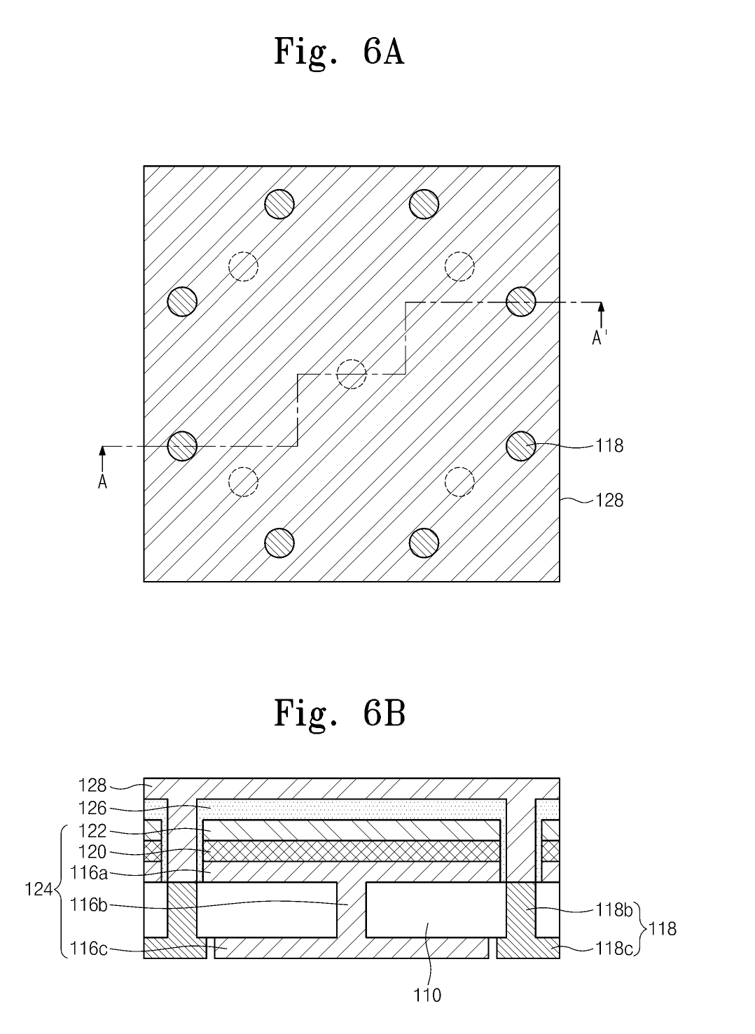

In embodiments where the first electrode 124 is used as the anode, the hole transfer layer and the hole injecting layer may be formed of materials whose highest occupied molecular orbital (HOMO) level is between a work function of the first electrode 124 and a HOMO level of the organic electroluminescent material. The electron transfer layer and the electron injecting layer may be formed of materials whose lowest unoccupied molecular orbital (LUNO) level is between a work function of a second electrode 128, which will be described with reference to FIGS. 6A and 6B, and a LUMO level of the organic electroluminescent material.

The hole transfer layer or the hole injecting layer may include at least one of diamines, MTDATA (4,4′,4″-tris(3-methylphenylphenylamino)triphenylamine), TPD (N,N′ -diphenyl-N,N′ -di(3 -methylphenyl)-1, 1 ‘ -biphenyl-4,4’ -diamine), 1,1-bis(4-dip-tolylaminophenyl)cyclohexane, N,N,N′,N′-tetra(2-naphthyl)-4,4-diamino-p-terphenyl, polypyrrole, polyaniline, or PEDOT/PSS (poly(3,4-ethylenedioxythiphene, polystyrene sulfonate). The electron injecting layer may include at least one of alkali metals, alkaline-earth metals, oxides of alkali metals, or oxides of alkaline-earth metals. The electron transfer layer may include at least one of tris(8-hydroxyquinolinato)aluminium derivative, o-, m-, or p-phenanthroline derivative, oxadiazole derivative, or triazole derivative.

The organic electroluminescent layer 126 may be formed by a deposition method using a shadow mask. In other embodiments, the formation of the organic electroluminescent layer 126 may include forming a layer (not shown) using a spin coating method or an inkjet printing method and then patterning the layer. The patterning of the layer may be performed using a photoresist pattern as an etch mask. The formation of the photoresist pattern may include forming a photoresist layer on the PCB substrate 110, performing an exposure process on the photoresist layer using an exposure mask, and developing the photoresist layer to open the second through electrode 118b.

Referring to FIGS. 1A, 1B, 6A and 6B, a second electrode 128 may be formed on the organic electroluminescent layer 126. The second electrode 128 may be electrically connected to the second through electrode 118b. The second electrode 128 may be configured to permit transmission of the light generated from the organic electroluminescent layer 126.

Structures of the second electrode 128 may vary depending on the first electrode 124. In embodiments in which the first electrode 124 includes the first conductive layer 116a, the first through electrode 116b, the second conductive layer 116c, the reflective layer 120, and the transparent conductive layer 122, the second electrode 128 may include a material with work-function lower than the transparent conductive layer 122. In example embodiments, the second electrode 128 may include at least one of silver (Ag), aluminum (Al), magnesium (Mg), molybdenum (Mo), or alloys thereof and be formed to a thickness (such as, for example, of about 25 nm or less) such that the light generated from the organic electroluminescent layer 126 can be transmitted toward the outside. In some embodiments, the transparent conductive layer 122 may serve as an anode supplying holes to the organic electroluminescent layer 126, and the second electrode 128 may serve as a cathode supplying electrons to the organic electroluminescent layer 128.

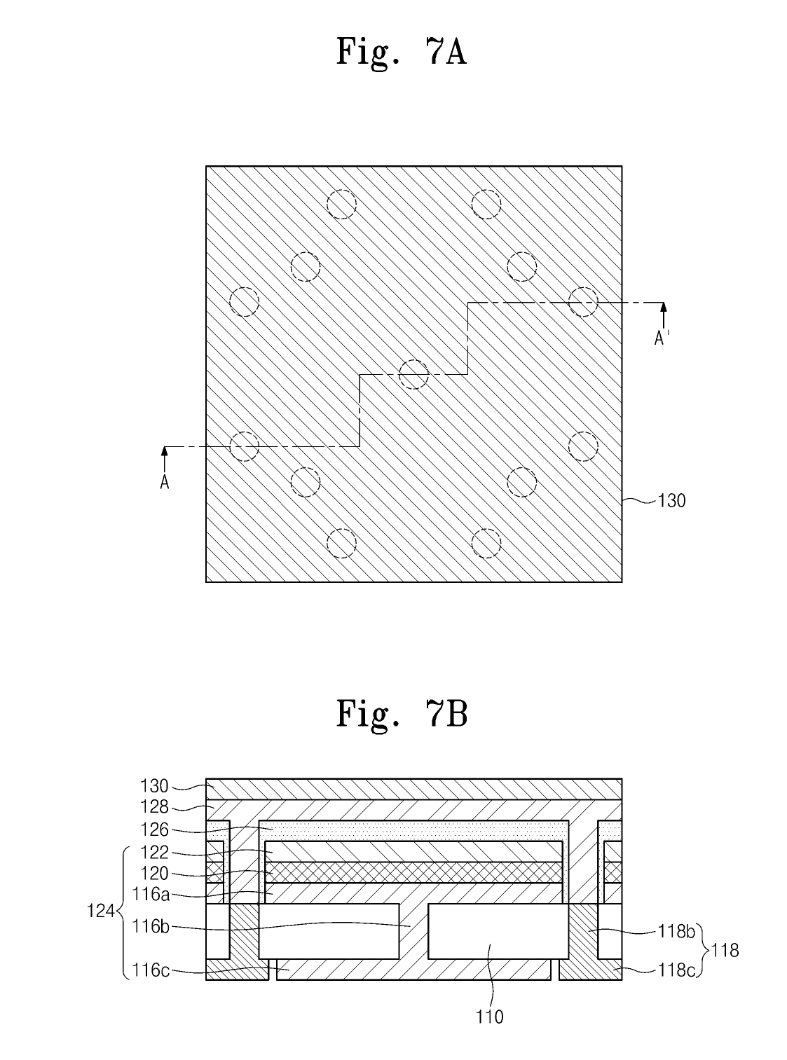

Referring to FIGS. 1A, 1B, 7A and 7B, an encapsulating layer 130 may be formed on the second electrode 128. The encapsulating layer 130 may provide protection against external moisture and oxygen. In some embodiments, the encapsulating layer 130 may include at least transparent material. In some embodiments, the encapsulating layer 130 may be formed of a glass substrate or a transparent insulating layer. When the encapsulating layer 130 is formed of an insulating layer, the encapsulating layer 130 may be formed using a deposition process. When the encapsulating layer 130 is a glass substrate, the encapsulating layer 130 may be provided with a structure attached to the second electrode 128 using a sealant.

In some embodiments, the encapsulating layer 130 may be wholly attached to the second electrode 128. In some embodiments, the encapsulating layer 130 may be locally attached to an edge region of the second electrode 128 and/or further include a hygroscopic element.

According to example embodiments, the OELD device 100A may be a top-emission type, in which a light generated from the organic electroluminescent layer 126 is emitted from a top surface of the encapsulating layer 130 via the second electrode 128. When there is an electric potential difference between the first electrode 124 and the second electrode 128 of the OELD device 100A, a portion of a light generated from the organic electroluminescent layer 126 may be irradiated outward through the second electrode 128. The remaining portion of the light may pass through the transparent conductive layer 122, be reflected by the reflective layer 120, and be irradiated outward through the transparent conductive layer 122, the organic electroluminescent layer 126, and the second electrode 128, sequentially.

For a conventional large-area OELD device, there may be a difficulty of dissipating heat generated therein. This may result in a deterioration of organic material in the OELD device, and furthermore bring about the unintended voltage drop phenomenon or a non-uniformity problem of display quality.

According to example embodiments, the first conductive layer 116a, the first through electrode 116b, and the second conductive layer 116c may be formed of metallic materials with a high thermal conductivity, and the first conductive layer 116a and the second conductive layer 116c may be connected with each other by the first through electrode 116b. As a result, the OELD device 100A according to example embodiments can effectively dissipate heat generated therein. In other words, the OELD device 100A can exhibit improved heat-dissipation efficiency. Furthermore, the first electrode 124 may be formed in the first region C of the PCB substrate 110, and the second electrode 128, which is connected to the second through electrode 118b, may extend over the first electrode 124. Accordingly, it is possible to reduce a distance between the first electrode 124 and the second electrode 128. In other words, the OELD device 100A may be configured to have a shortened current path. As a result, the non-uniformity problem of display quality can be overcome. Furthermore, it is possible to prevent the unintended voltage drop phenomenon from occurring in the OELD device 100A, because metal layers are formed in/on the PCB substrate 110 with enough thickness to achieve low resistance.

In addition, according to example embodiments, the PCB substrate 110 may be used as a deposition substrate for the OELD device 100A. As a result, an additional electrode portion for operating the organic electroluminescent layer 126 does not need to be formed on the PCB substrate 110. This enables to increase a light-emitting area of the OELD device 100A.

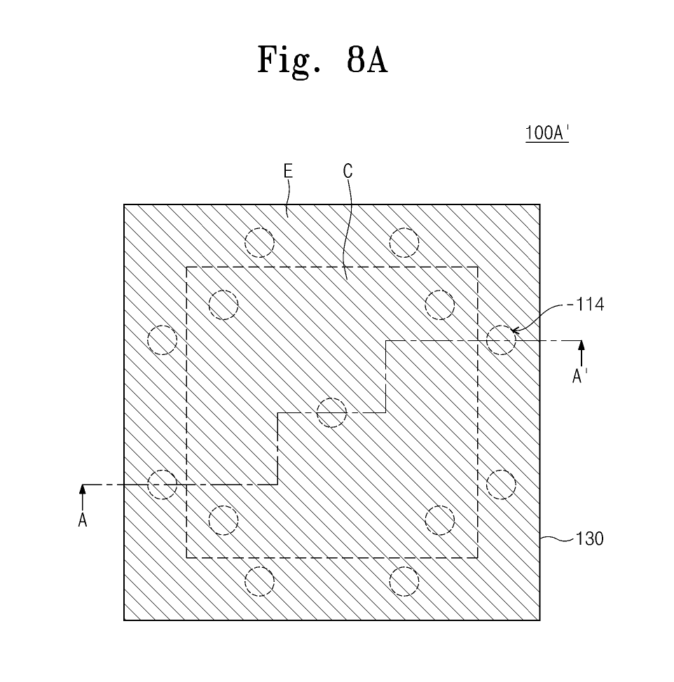

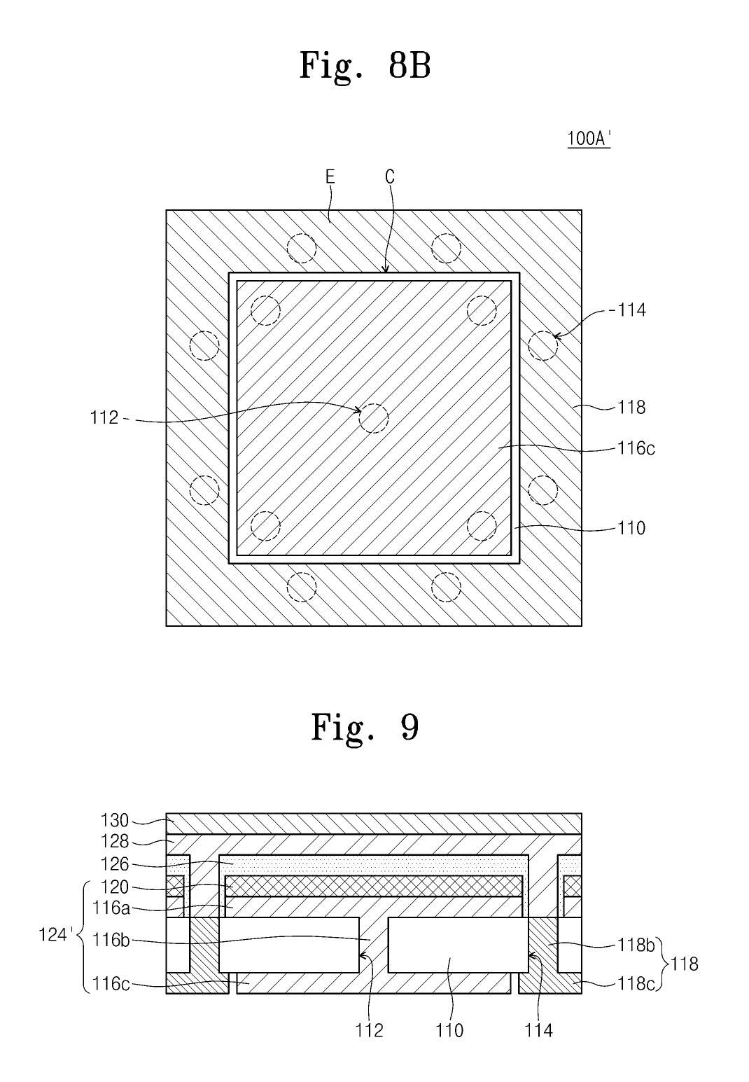

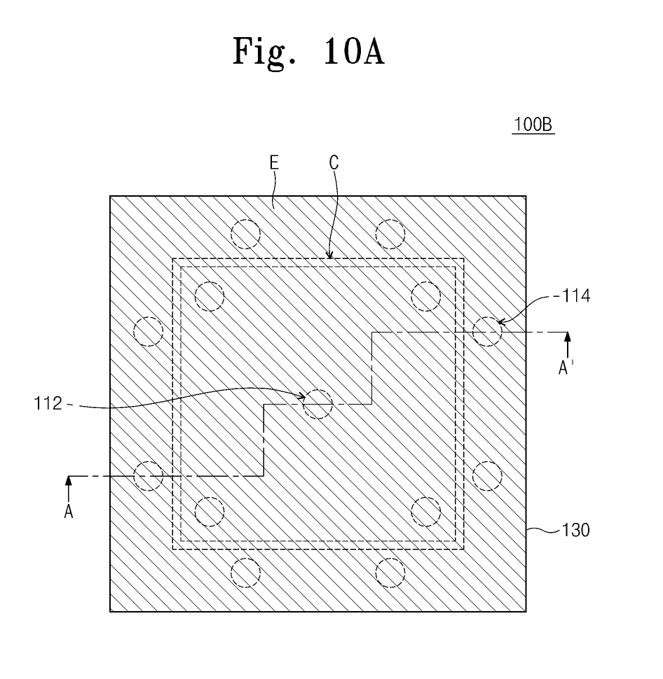

FIGS. 8A and 8B are top and bottom plan views of an embodiment of an OELD device with an inverted structure, FIG. 9 is a sectional view taken along a dotted line A-A′ of FIG. 8A. For concise description, a previously described element may be identified by a similar or identical reference number without repeating an overlapping description thereof.

Referring to FIGS. 8A, 8B and 9, an OELD device 100A′ with the inverted structure may be provided. The OELD device 100A′ may include the PCB substrate 110, a first electrode 124′, the organic electroluminescent layer 126, the second electrode 128, and the connection electrode 118 electrically connected to the second electrode 128.

The first electrode 124′ may include the first conductive layer 116a, the first through electrode 116b, the second conductive layer 116c, and the reflective layer 120.

The first electrode 124′ may serve as a cathode supplying electrons to the organic electroluminescent layer 126. In some embodiments, the second conductive layer 116c and the reflective layer 120 may contribute to improve heat-dissipation efficiency and reflectance of the OELD device 100A′ and to suppress an unintended voltage drop phenomenon. In other embodiments, the OELD device 100A′ may not include the second conductive layer 116c and the reflective layer 120.

The second electrode 128 may be formed of a transparent electrode having a higher work function than the first electrode 124′. In some embodiments, the second electrode 128 may be formed of one of transparent conductive oxides, such as, for example, indium-tin-oxide (ITO), indium-zinc-oxide (IZO), aluminum zinc oxide (AZO), gallium doped zinc oxide (GZO), zinc tin oxide (ZTO), gallium tin oxide (GTO), and fluorine doped tin oxide (FTO). In some embodiments, the second electrode 128 may serve as an anode supplying holes to the organic electroluminescent layer 126.

The connection electrode 118 may include the second through electrode 118b and the third conductive layer 118c. The third conductive layer 118c may contribute to reduce an unintended voltage drop phenomenon. In other embodiments, the OELD device 100A′ may not include the third conductive layer 118c.

The first electrode 124′ and the second electrode 128 may be used as the cathode and the anode of the OELD device 100A′, respectively, and the first electrode 124′ may not include a transparent electrode provided on the reflective layer 120. Except for these points, the OELD device 100A′ may be the same as the OELD device 100A, which was described with reference to FIGS. 1A through 7A, in terms of materials and/or forming methods of elements thereof. Although the OELD device 100A of FIG. 7B may exhibit improved properties compared with the OELD device 100A′ of FIG. 9, the OELD device 100A′ of FIG. 9 may exhibit the substantially same properties as the OELD device 100A of FIG. 7B in terms of, forexample, light-emitting area, a heat-dissipation efficiency, and the unintended voltage drop phenomenon.

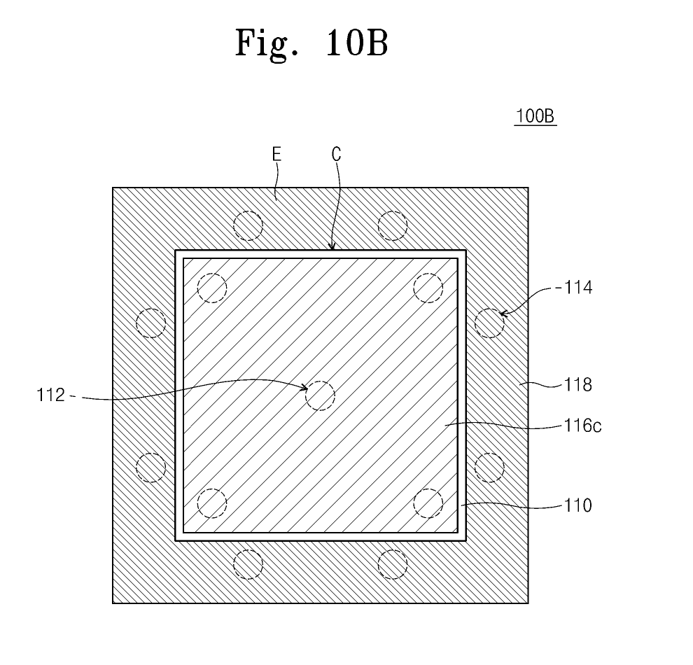

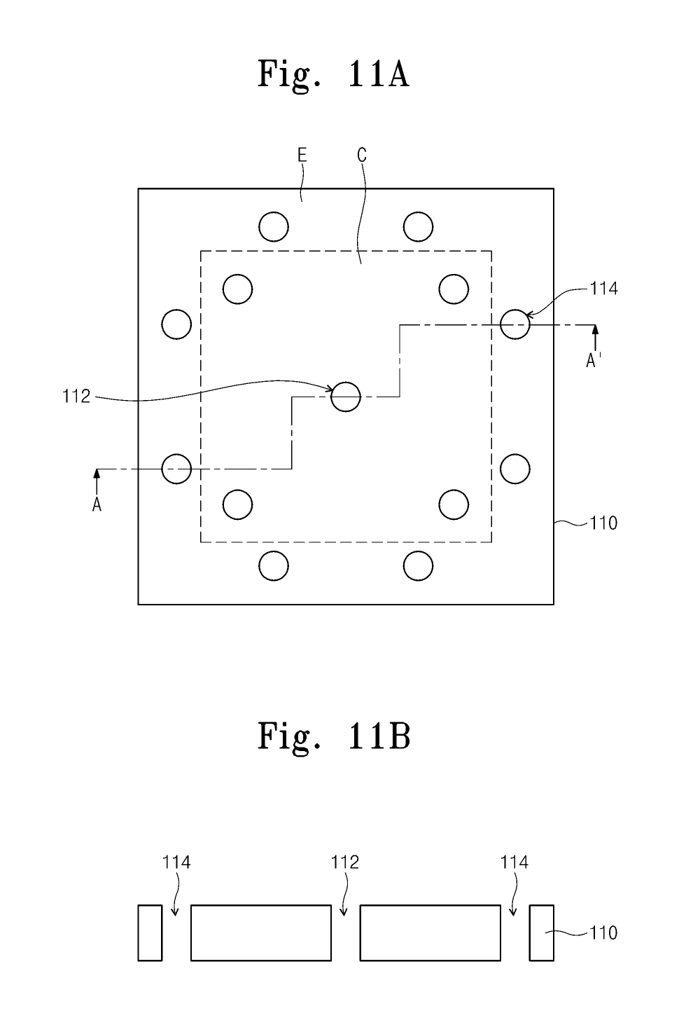

FIGS. 10A and 10B are top and bottom plan views of another embodiment of an OELD device. FIGS. 11A through 16A are plan views illustrating another embodiment of a method of fabricating an OELD device, and FIGS. 11B through 16B are sectional views taken along dotted lines A-A′ of FIGS. 11A through 16A, respectively. For concise description, a previously described element may be identified by a similar or identical reference number without repeating an overlapping description thereof.

Referring to FIGS. 10A, 10B, 11A and 11B, an organic electroluminescent display (OELD) device 100B may include a printed circuit board (PCB) substrate 110. The PCB substrate 110 may include a first region C including at least one first through hole 112 and a second region E including at least one second through hole 114. The second region E may be provided to surround the first region C.

The PCB substrate 110 and the first and second through holes 112 and 114 may be prepared using the same method as the embodiment described with reference to FIGS. 2A and 2B.

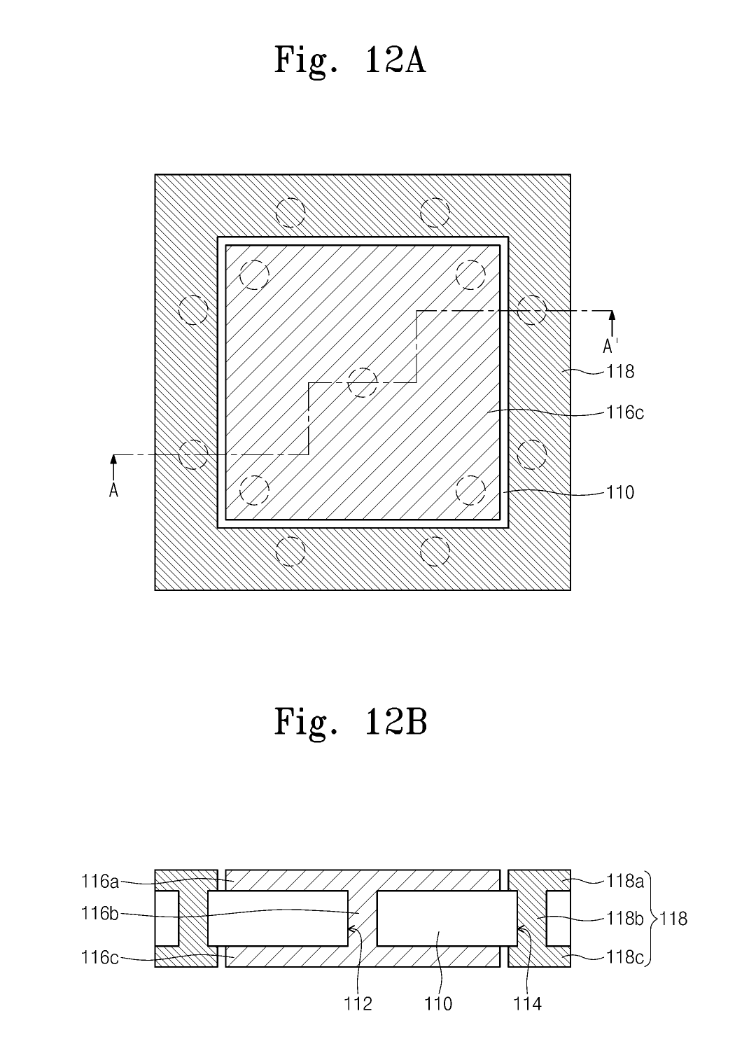

Referring to FIGS. 10A, 10B, 12A and 12B, a first through electrode 116b may be formed in the first through hole 112, and a second through electrode 118b may be formed in the second through hole 114. A first conductive layer 116a may be formed on the first through electrode 116b and the PCB substrate 110. A second conductive layer 116c may be formed below the first through electrode 116b and the PCB substrate 110.

A third conductive layer 118c may be formed below the second through electrode 118b and the PCB substrate 110, and a fourth conductive layer 118a may be formed on the second through electrode 118b and the PCB substrate 110. In some embodiments, the third conductive layer 118c may be formed along the second region E of the PCB substrate 110, and the fourth conductive layer 118a may be formed along the second region E of the PCB substrate 110. The third conductive layer 118c may be spaced apart from the second conductive layer 116c and have a closed loop shape surrounding the second conductive layer 116c. The fourth conductive layer 118a may be spaced apart from the first conductive layer 116a and have a closed loop shape surrounding the first conductive layer 116a. From a plan view, the third conductive layer 118c may occupy the same region of the PCB substrate 110 as the fourth conductive layer 118a. The fourth conductive layer 118a, the second through electrode 118b and the third conductive layer 118c may constitute a connection electrode 118.

In some embodiments, the first conductive layer 116a, the first through electrode 116b, the second conductive layer 116c, the second through electrode 118b, and the third conductive layer 118c may be formed using the same method as the example embodiments described with reference to FIGS. 3A and 3B. The fourth conductive layer 118a may be configured in such a way that a total reflection may occur in the OELD device 100B. In some embodiments, the fourth conductive layer 118a may be formed of a metal layer with a high thermal conductivity, such as copper (Cu) or gold (Au).

The first conductive layer 116a, the first through electrode 116b, the second conductive layer 116c, and the connection electrode 118 may be thick enough to achieve low resistance and suppress an unintended voltage drop phenomenon.

In some embodiments, the second conductive layer 116c may contribute to improve heat-dissipation efficiency and to suppress an unintended voltage drop phenomenon. Similarly, the third and fourth conductive layers 118c and 118a may contribute to suppress the unintended voltage drop phenomenon. In other embodiments, the OELD device 100B may not include the second conductive layer 116c and/or the third and fourth conductive layer 118c and 118a.

The formation of the first conductive layer 116a, the first through electrode 116b, the second conductive layer 116c, and the connection electrode 118 may include forming a layer using at least one of a plating method, a printing method such as a screen printing technique, a depositing method or any combination thereof, and then patterning the layer.

In some embodiments, the first and second through electrodes 116b and 118b may be formed by filling the first and second through holes 112 and 114 with a metallic paste using a screen printing technique. Thereafter, a layer (not shown) may be formed on and below the PCB substrate 110 provided with the first and second through electrodes 116b and 118b using a plating technique and the layer may be patterned to form the first, second, third, and fourth conductive layers 116a, 116c, 118c, and 118a.

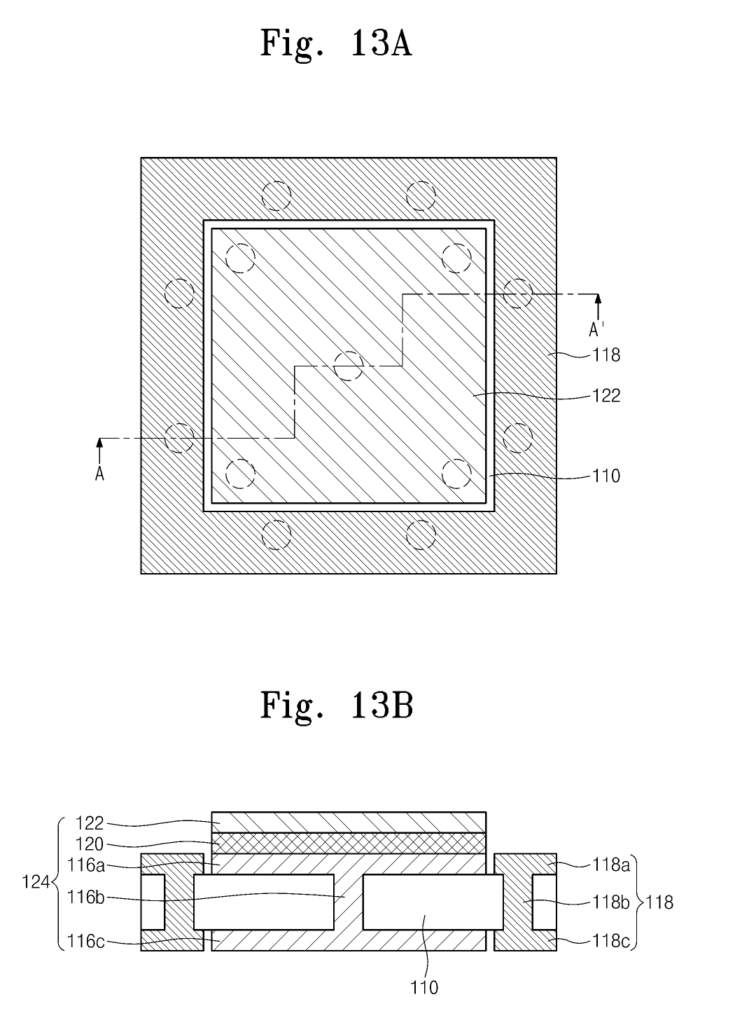

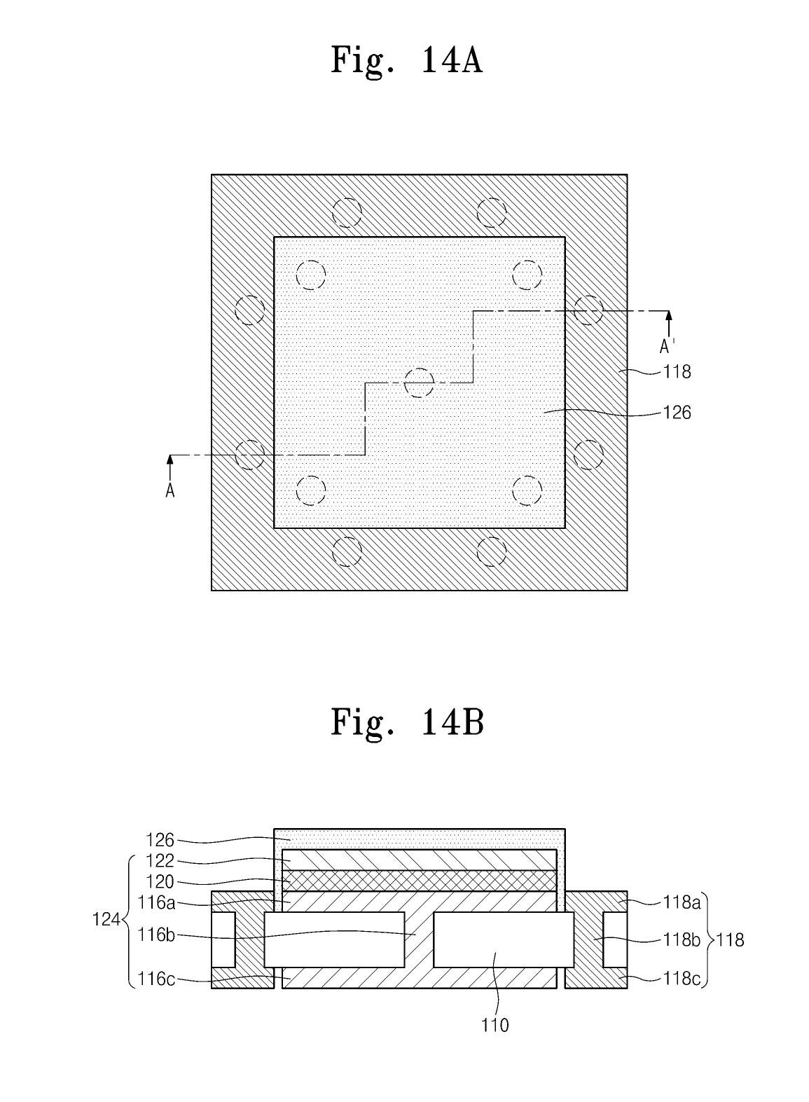

Referring to FIGS. 10A, 10B, 13A and 13B, a reflective layer 120 and a transparent conductive layer 122 may be sequentially formed on the first conductive layer 116a. In some embodiments, the reflective layer 120 and the transparent conductive layer 122 may be locally formed on the first conductive layer 116a in the first region C. Except for this point, the reflective layer 120 and the transparent conductive layer 122 may be formed using the same method as the example embodiments described with reference to FIGS. 4A and 4B.

According to other embodiments, the first conductive layer 116a, the first through electrode 116b, the second conductive layer 116c, the reflective layer 120, and the transparent conductive layer 122 may constitute a first electrode 124. In some embodiments, the first electrode 124 may serve as an anode supplying holes to an organic electroluminescent layer to be subsequently formed.

In embodiments where the first electrode 124 includes the reflective layer 120, the OELD device 100B can exhibit improved heat dissipation and reflectance characteristics. Accordingly, it is possible to increase the life time and performance efficiency of the OELD device 100B. In embodiments where the first electrode 124 includes the transparent conductive layer 122, the OELD device 100B can exhibit improved uniformity of brightness without the need of an additional auxiliary electrode. The reflective layer 120 and the transparent conductive layer 122 may contribute to improve properties of the OELD device 100B, such as heat dissipation, reflectance and brightness uniformity. In other embodiments, the OELD device 100B may not include the reflective layer 120 and the transparent conductive layer 122.

Referring to FIGS. 10A, 10B, 14A and 14B, an organic electroluminescent layer 126 may be formed on the first electrode 124. In some embodiments, the organic electroluminescent layer 126 may be locally formed in the first region C. Except for this point, the organic electroluminescent layer 126 may be formed using the same method and material as the example embodiments described with reference to FIGS. 5A and 5B.

The organic electroluminescent layer 126 may be formed by a deposition method using a shadow mask. In some embodiments, the formation of the organic electroluminescent layer 126 may include forming a layer (not shown) using a spin coating method or an inkjet printing method and then patterning the layer. The patterning of the layer may be performed using a photoresist pattern as an etch mask. The formation of the photoresist pattern may include forming a photoresist layer on the PCB substrate 110, performing an exposure process on the photoresist layer using an exposure mask, and developing the photoresist layer to open the fourth conductive layer 118a.

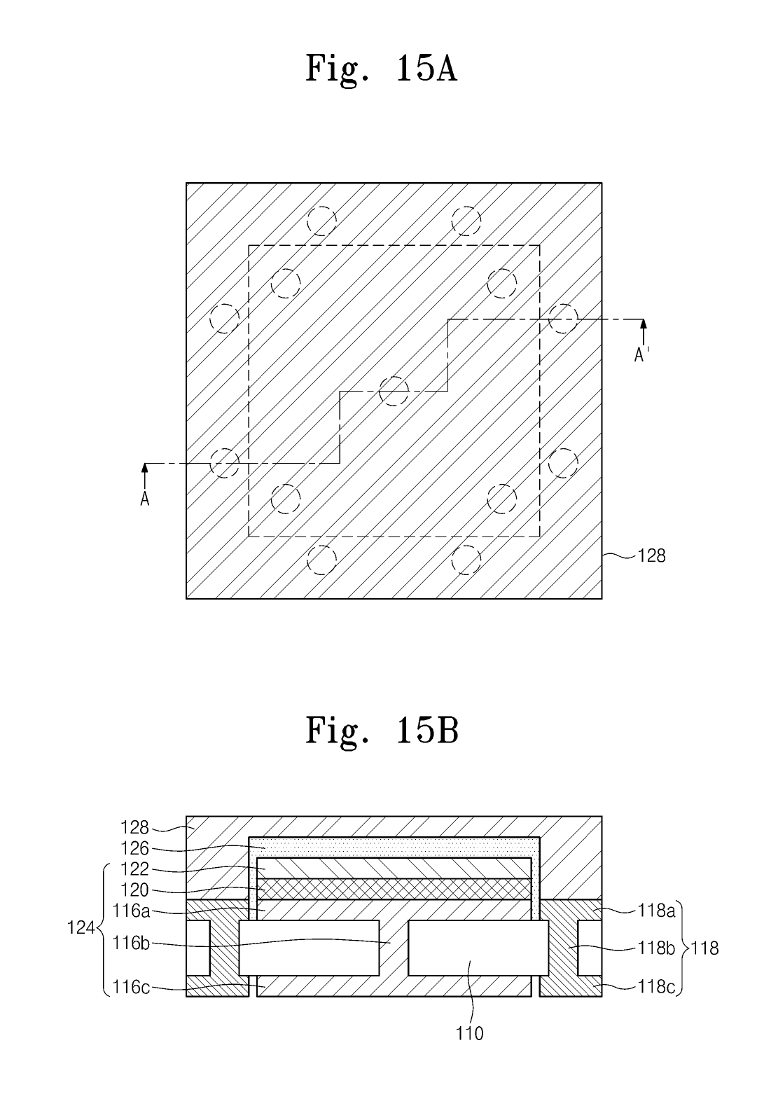

Referring to FIGS. 10A, 10B, 15A and 15B, a second electrode 128 may be formed on the organic electroluminescent layer 126. The second electrode 128 may be electrically connected to the connection electrode 118.

In some embodiments, the second electrode 128 may be formed on the organic electroluminescent layer 126 and the fourth conductive layer 118a. Except for features related to a spatial position of the second electrode 128, the second electrode 128 may be formed using the same method and material as the example embodiments described with reference to FIGS. 6A and 6B.

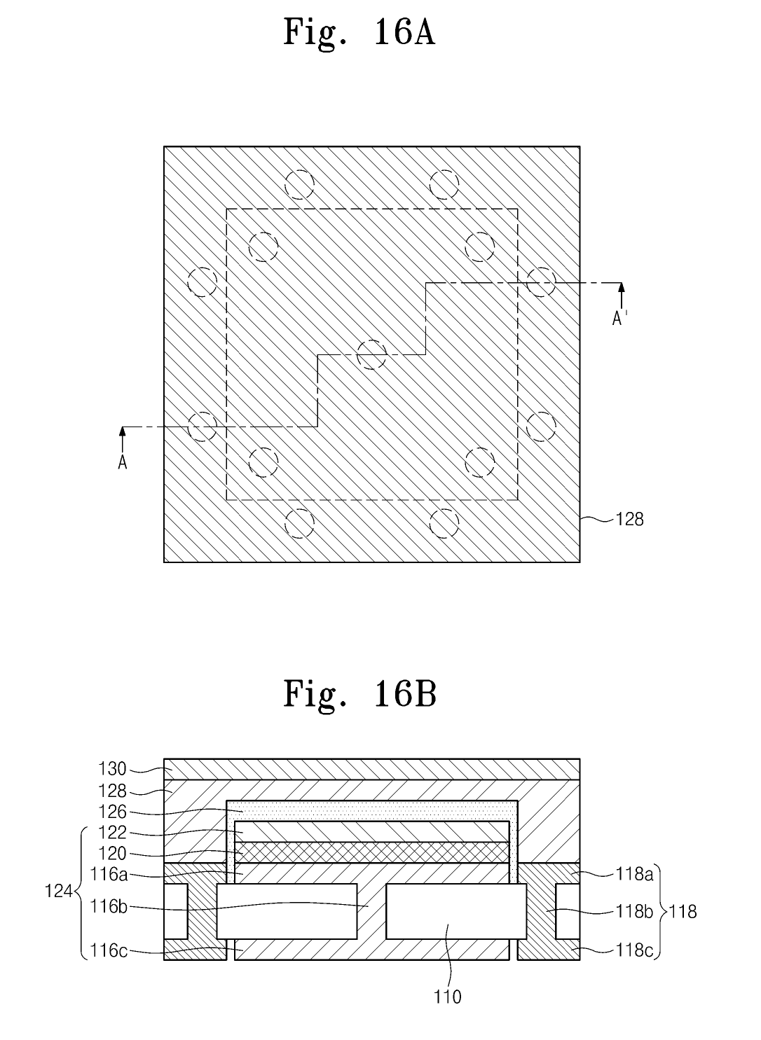

Referring to FIGS. 10A, 10B, 16A and 16B, an encapsulating layer 130 may be formed on the second electrode 128. The encapsulating layer 130 may be formed using the same method and material as the example embodiments described with reference to FIGS. 7A and 7B.

According to other embodiments, the OELD device 100B may be a top-emission type, in which a light generated from the organic electroluminescent layer 126 is emitted from a top surface of the encapsulating layer 130 via the second electrode 128. When there is an electric potential difference between the first electrode 124 and the second electrode 128 of the OELD device 100B, a portion of a light generated from the organic electroluminescent layer 126 may be irradiated outward through the second electrode 128. The remaining portion of the light may pass through the transparent conductive layer 122, be reflected by the reflective layer 120, and be irradiated outward through the transparent conductive layer 122, the organic electroluminescent layer 126, and the second electrode 128, sequentially.

According to other example embodiments, the PCB substrate 110 may be used as a deposition substrate for the OELD device 100B. As a result, an additional electrode portion for operating the organic electroluminescent layer 126 does not need to be formed on the PCB substrate 110. This enables to increase a light-emitting area of the OELD device 100B. In addition, the first electrode 124 may be formed in the first region C of the PCB substrate 110, and the second electrode 128, which is connected to the second through electrode 118b, may extend over the first electrode 124. Accordingly, it is possible to reduce a distance between the first electrode 124 and the second electrode 128, and the OELD device 100B may be configured to have a shortened current path. As a result, the OELD device 100B can overcome the non-uniformity problem of display quality. Furthermore, when compared with the OELD device 100A of FIG. 7A, the connection electrode 118 may additionally include the fourth conductive layer 118a and thus enable to improve a voltage drop phenomenon of the OELD device 100B.

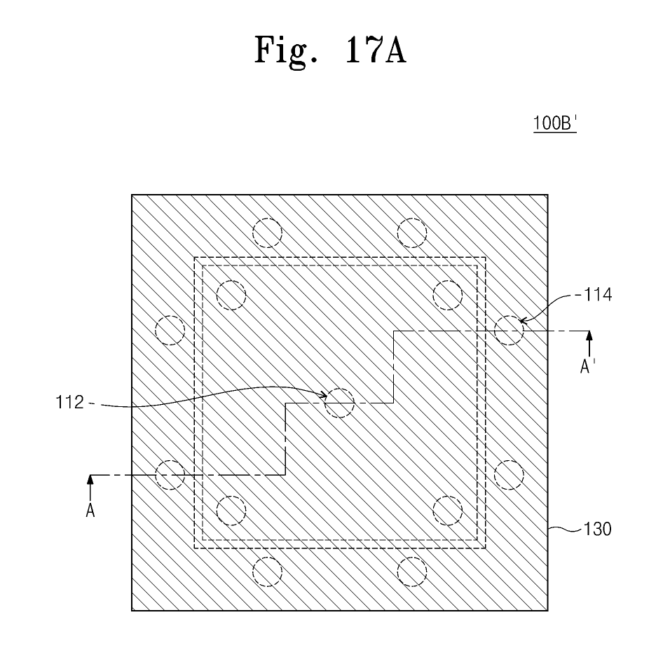

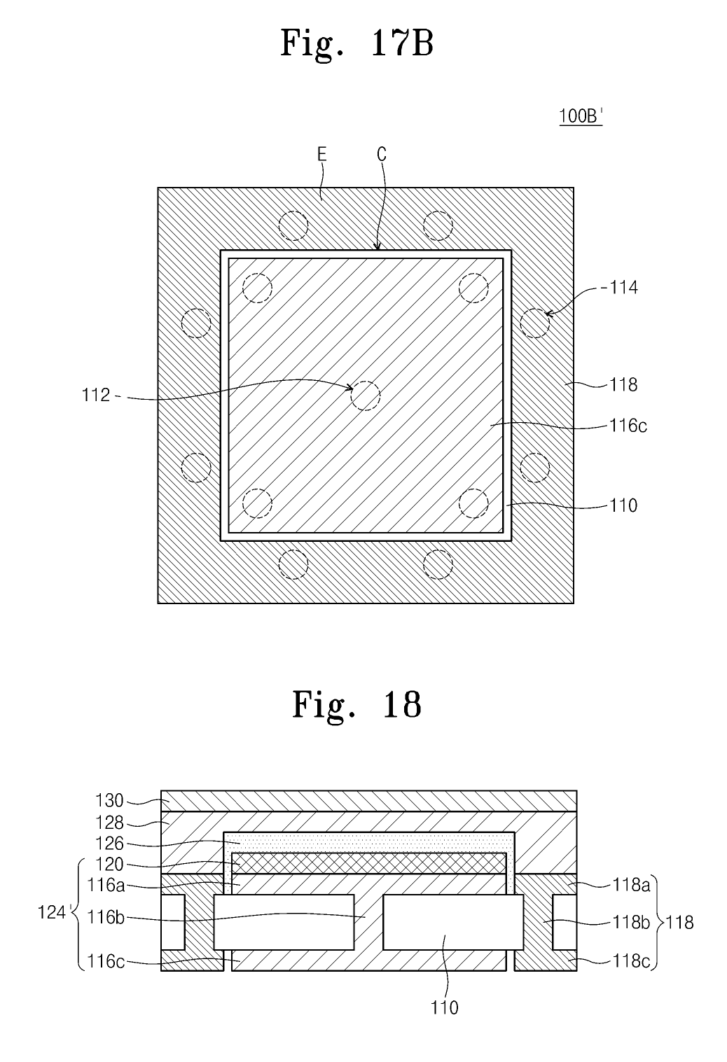

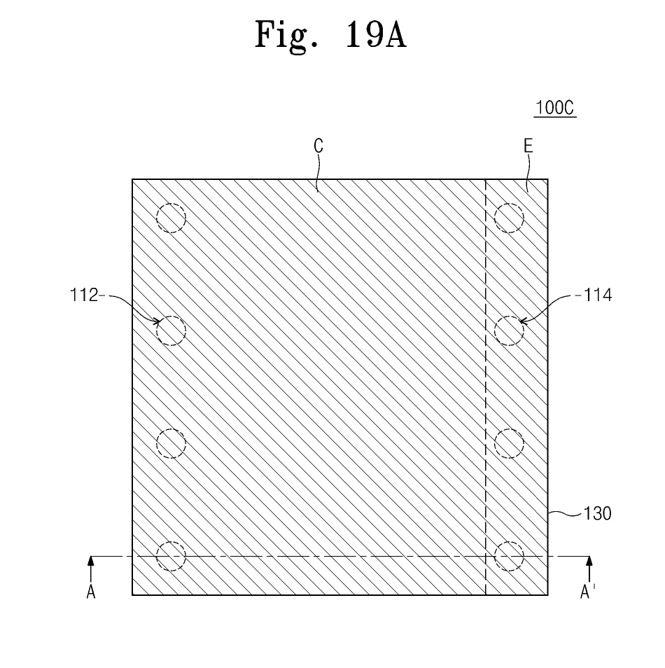

FIGS. 17A and 17B are top and bottom plan views of another embodiment of an OELD device with an inverted structure, and FIG. 18 is a sectional view taken along a dotted line A-A′ of FIG. 17A. For concise description, an element previously described with reference to FIGS. 10A through 16A and 10B through 16B may be identified by a similar or identical reference number without repeating an overlapping description thereof.

Referring to FIGS. 17A, 17B and 18, an OELD device 100B′ with the inverted structure may be provided. The OELD device 100B′ may include the PCB substrate 110, a first electrode 124′, the organic electroluminescent layer 126, the second electrode 128, and the connection electrode 118 electrically connected to the second electrode 128.

The first electrode 124′ may include the first conductive layer 116a, the first through electrode 116b, the second conductive layer 116c, and the reflective layer 120. The first electrode 124′ may serve as a cathode supplying electrons to the organic electroluminescent layer 126. In some embodiments, the second conductive layer 116c and the reflective layer 120 may contribute to improve heat-dissipation efficiency and reflectance of the OELD device 100B′ and to suppress an unintended voltage drop phenomenon. In other embodiments, the OELD device 100B′ may not include the second conductive layer 116c and the reflective layer 120.

The second electrode 128 may be formed of a transparent electrode having a higher work function than the first electrode 124′. In some embodiments, the second electrode 128 may be formed of an ITO layer or an IZO layer. In some embodiments, the second electrode 128 may serve as an anode supplying holes to the organic electroluminescent layer 126.

The connection electrode 118 may include the fourth conductive layer 118a, the second through electrode 118b, and the third conductive layer 118c. The third conductive layer 118c and the fourth conductive layer 118a may contribute to reduce an unintended voltage drop phenomenon. However, example embodiments may not be limited thereto; for example, the OELD device 100B′ may not include the third conductive layer 118c and/or the fourth conductive layer 118a.

In these embodiments, the first electrode 124′ and the second electrode 128 may be used as the cathode and the anode of the OELD device 100B′, respectively, and the first electrode 124′ may not include a transparent electrode provided on the reflective layer 120. Except for these points, the OELD device 100B′ may be the same as the OELD device 100B, which was described with reference to FIGS. 10A through 16A and 10B through 16B, in terms of materials and/or forming methods of elements thereof. Although the OELD device 100B of FIG. 16B may exhibit improved properties compared with the OELD device 100B′ of FIG. 18, the OELD device 100B′ of FIG. 18 may exhibit the substantially same properties as the OELD device 100B of FIG. 16B in terms of, for example, light-emitting area, a heat-dissipation efficiency, and the unintended voltage drop phenomenon.

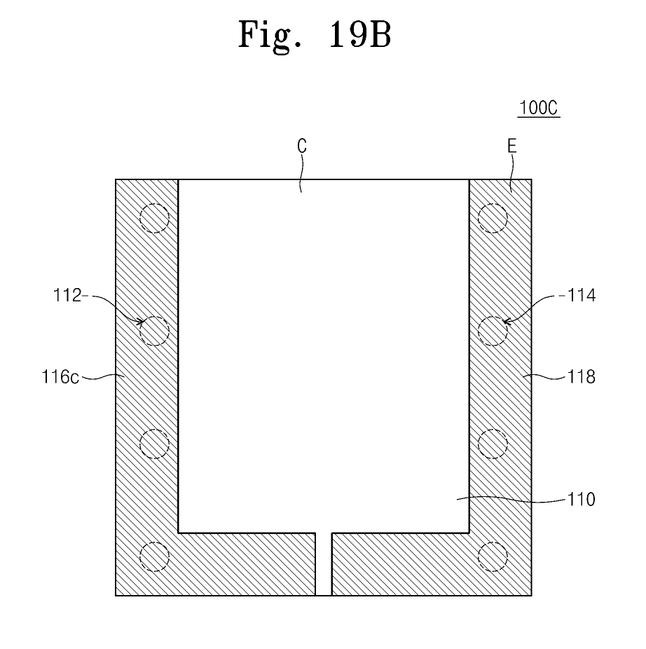

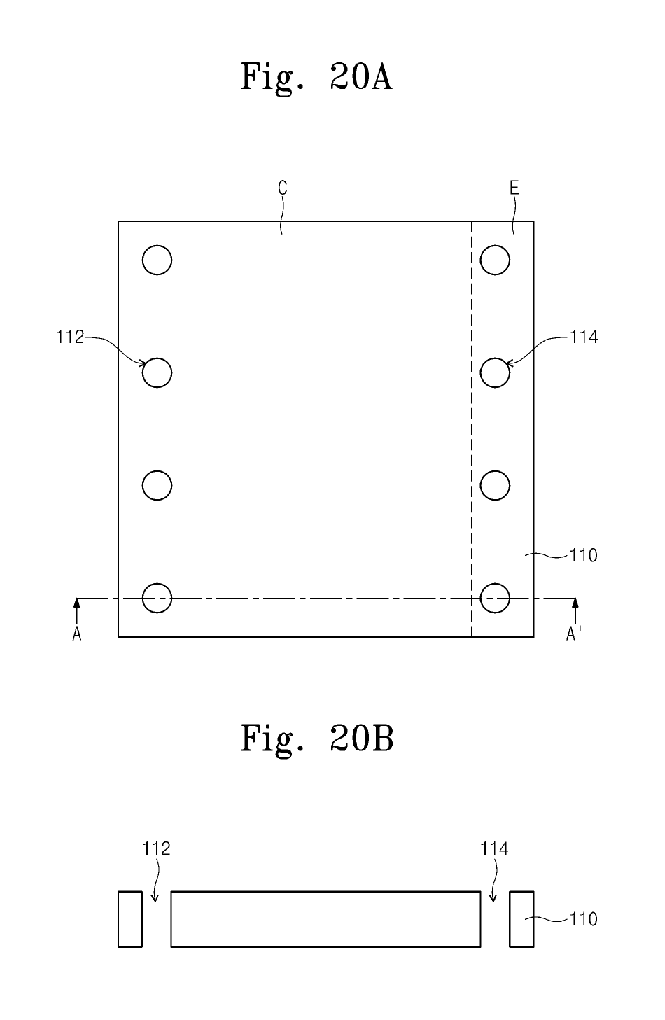

FIGS. 19A and 19B are top and bottom plan views of another embodiment of an OELD device . FIGS. 20A through 25A are plan views illustrating another embodiment of a method of fabricating an OELD device, and FIGS. 20B through 25B are sectional views taken along dotted lines A-A′ of FIGS. 20A through 25A, respectively. For concise description, a previously described element may be identified by a similar or identical reference number without repeating an overlapping description thereof.

Referring to FIGS. 19A, 19B, 20A and 20B, an OELD device 100C may include a printed circuit board (PCB) substrate 110. The PCB substrate 110 may include a first region C including at least one first through hole 112 and a second region E including at least one second through hole 114. The first region C may be provided adjacent to one edge of the PCB substrate 110 and the second region E may be provided adjacent to another edge of the PCB substrate 110 opposite the one edge thereof.

The PCB substrate 110 and the first and second through holes 112 and 114 may be prepared in the same manner as that of the example embodiments described with reference to FIGS. 2A and 2B, except for arrangement of the first and second through holes 112 and 114.

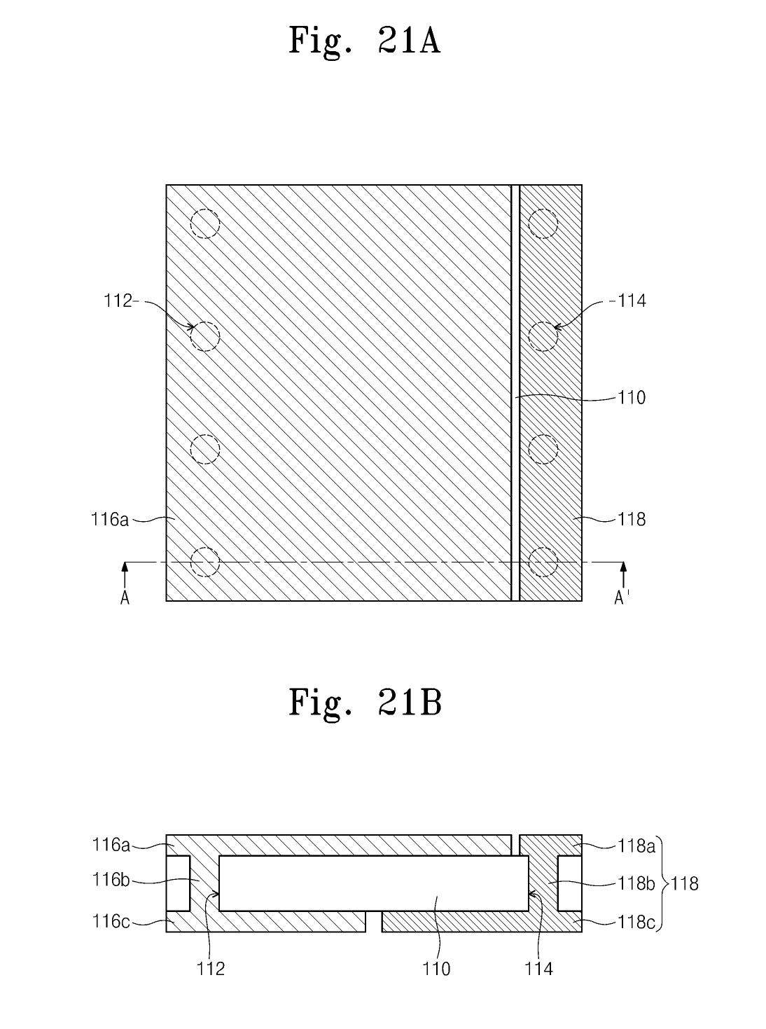

Referring to FIGS. 19A, 19B, 21A and 21B, a first through electrode 116b may be formed in the first through hole 112, and a second through electrode 118b may be formed in the second through hole 114. A first conductive layer 116a may be formed on the first through electrode 116b and the PCB substrate 110. A second conductive layer 116c may be formed below the first through electrode 116b and the PCB substrate 110. The second conductive layer 116c may extend from the one edge of the PCB substrate 110 to a region adjacent thereto. In some embodiments, the second conductive layer 116c may be formed to have an ‘L’-shaped section.

A third conductive layer 118c may be formed below the second through electrode 118b and the PCB substrate 110. The third conductive layer 118c may be spaced apart from the second conductive layer 116c and extend from the opposite edge of the PCB substrate 110 to a region adjacent thereto. In some embodiments, the third conductive layer 118c may be formed to have an ‘L’-shaped section. The third conductive layer 118c may extend from the second region E to the first region C. In some embodiments, the third conductive layer 118c and the second conductive layer 116c may be symmetric with each other relative to a plane perpendicular to a top surface of the PCB substrate 110. In some embodiments, extended portions of the third conductive layer 118c and the second conductive layer 116c may be opposite to each other and be spaced apart from each other.

A fourth conductive layer 118a may be formed on the second through electrode 118b and the PCB substrate 110 in the second region E of the PCB substrate 110. The fourth conductive layer 118a may be spaced apart from the first conductive layer 116a. From a plan view, the fourth conductive layer 118a may be provided adjacent to the opposite edge of the PCB substrate 110. In some embodiments, the fourth conductive layer 118a, the second through electrode 118b and the third conductive layer 118c may constitute a connection electrode 118.

In some embodiments, the first conductive layer 116a, the first through electrode 116b, the second conductive layer 116c, and the connection electrode 118 may be formed in the same manner as that of the example embodiments described with reference to FIGS. 3A and 3B or FIGS. 12A and 12B.

The first conductive layer 116a, the first through electrode 116b, the second conductive layer 116c, and the connection electrode 118 may be thick enough to achieve low resistance and suppress an unintended voltage drop phenomenon.

In some embodiments, the second conductive layer 116c may contribute to improve heat-dissipation efficiency and to suppress an unintended voltage drop phenomenon. Similarly, the third and fourth conductive layer 118c and 118a may contribute to suppress the unintended voltage drop phenomenon. In other embodiments, the OELD device 100C may not include the second conductive layer 116c and/or the third and fourth conductive layer 118c and 118a.

The formation of the first conductive layer 116a, the first through electrode 116b, the second conductive layer 116c, and the connection electrode 118 may include forming a layer using at least one of a plating method, a printing method such as a screen printing technique, a depositing method or any combination thereof, and then patterning the layer. In some embodiments, the first to fourth conductive layers 116a, 116c, 118c, and 118a may be formed in the same manner as that of the example embodiment described with reference to FIGS. 21A and 21B, except for shapes or structures of the first to fourth conductive layers 116a, 116c, 118c, and 118a.

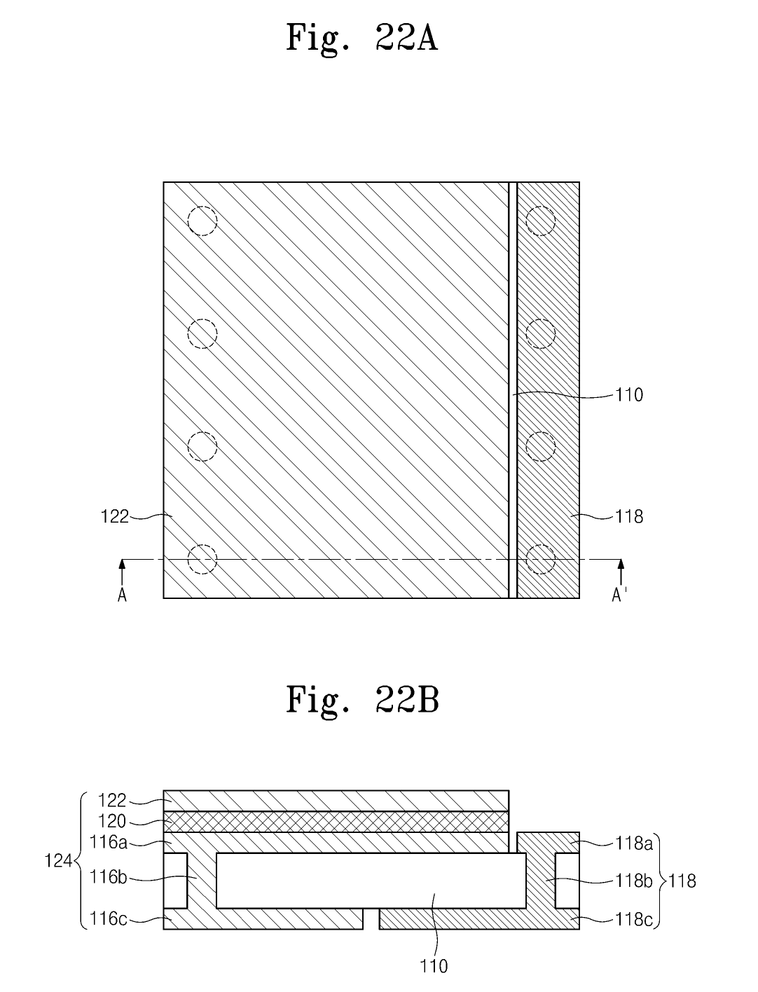

Referring to FIGS. 19A, 19B, 22A and 22B, a reflective layer 120 and a transparent conductive layer 122 may be sequentially formed on the first conductive layer 116a. The reflective layer 120 and the transparent conductive layer 122 may be formed to expose the connection electrode 118.

In some embodiments, the reflective layer 120 and the transparent conductive layer 122 may be locally formed on the first conductive layer 116a in the first region C. Except for this point, the reflective layer 120 and the transparent conductive layer 122 may be formed using the same method and material as the example embodiment described with reference to FIGS. 4A and 4B.

According to other embodiments, the first conductive layer 116a, the first through electrode 116b, the second conductive layer 116c, the reflective layer 120, and the transparent conductive layer 122 may constitute a first electrode 124. In some embodiments, the first electrode 124 may serve as an anode supplying holes to an organic electroluminescent layer (not shown) to be subsequently formed.

In embodiments where the first electrode 124 includes the reflective layer 120, the OELD device 100C can exhibit improved heat dissipation and reflectance characteristics. Accordingly, it is possible to increase the life time and efficiency of the OELD device 100C. In embodiments where the first electrode 124 includes the transparent conductive layer 122, the OELD device 100C can exhibit improved uniformity of brightness without the need of an additional auxiliary electrode. The reflective layer 120 and the transparent conductive layer 122 may contribute to improve properties of the OELD device 100C, such as heat dissipation, reflectance and brightness uniformity, but embodiments may not be limited thereto. In some embodiments, the OELD device 100C may not include the reflective layer 120 and the transparent conductive layer 122.

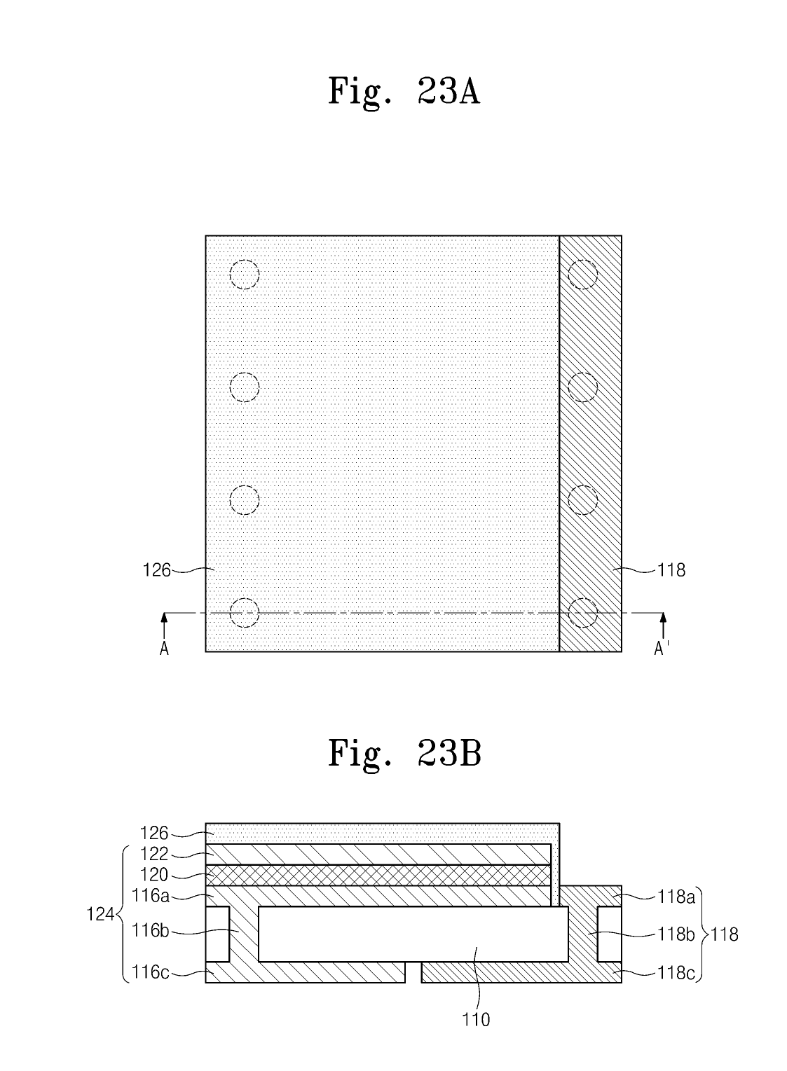

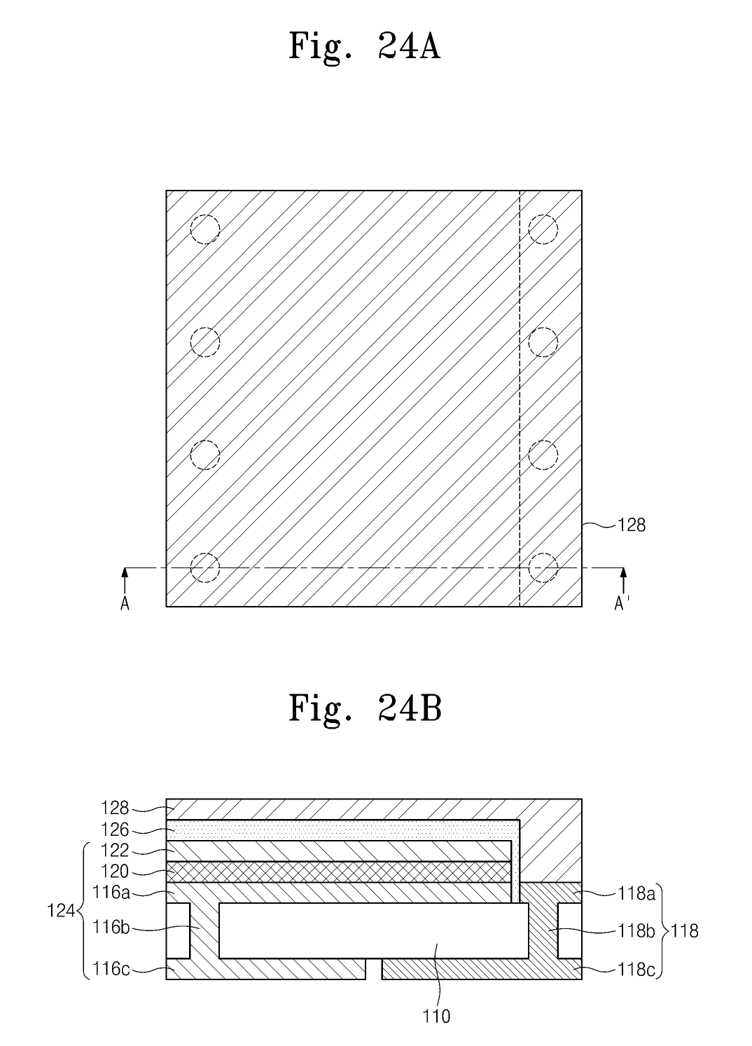

Referring to FIGS. 19A, 19B, 23A and 23B, an organic electroluminescent layer 126 may be formed on the first electrode 124. In some embodiments, the organic electroluminescent layer 126 may be locally formed in the first region C. Except for this point, the organic electroluminescent layer 126 may be formed using the same method and material as the example embodiments described with reference to FIGS. 5A and 5B.

The organic electroluminescent layer 126 may be formed by a deposition method using a shadow mask. In some embodiments, the formation of the organic electroluminescent layer 126 may include forming a layer (not shown) using a spin coating method or an inkjet printing method and then patterning the layer. The patterning of the layer may be performed using a photoresist pattern as an etch mask. The formation of the photoresist pattern may include forming a photoresist layer on the PCB substrate 110, performing an exposure process on the photoresist layer using an exposure mask, and developing the photoresist layer to open the fourth conductive layer 118a.

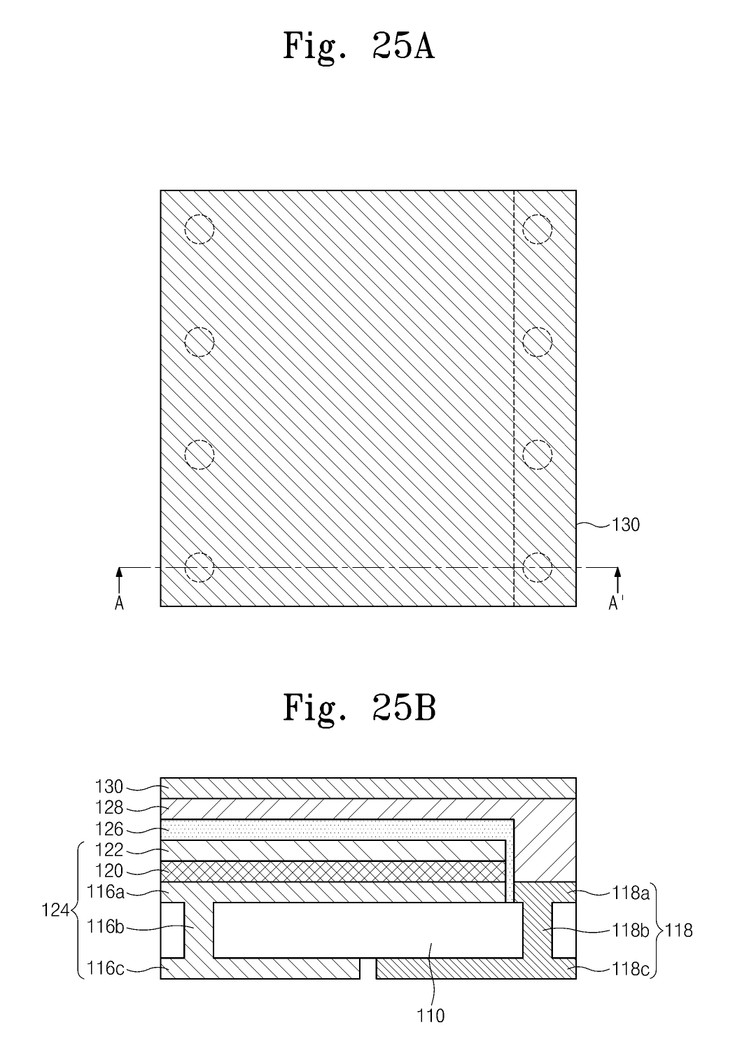

Referring to FIGS. 19A, 19B, 24A and 24B, a second electrode 128 may be formed on the organic electroluminescent layer 126. The second electrode 128 may be electrically connected to the connection electrode 118.

In some embodiments, the second electrode 128 may be formed on the organic electroluminescent layer 126 and the fourth conductive layer 118a. Except for features related to a spatial position of the second electrode 128, the second electrode 128 may be formed using the same method and material as the example embodiments described with reference to FIGS. 6A and 6B.

Referring to FIGS. 19A, 19B, 25A and 25B, an encapsulating layer 130 may be formed on the second electrode 128. The encapsulating layer 130 may be formed using the same method and material as the example embodiments described with reference to FIGS. 7A and 7B.

According to other embodiments, the OELD device 100C may be a top-emission type, in which a light generated from the organic electroluminescent layer 126 is emitted from a top surface of the encapsulating layer 130 via the second electrode 128. When there is an electric potential difference between the first electrode 124 and the second electrode 128 of the OELD device 100C, a portion of a light generated from the organic electroluminescent layer 126 may be irradiated outward through the second electrode 128. The remaining portion of the light may pass through the transparent conductive layer 122, be reflected by the reflective layer 120, and be irradiated outward through the transparent conductive layer 122, the organic electroluminescent layer 126, and the second electrode 128, sequentially.

According to other embodiments, the PCB substrate 110 may be used as a deposition substrate for the OELD device 100C. As a result, an additional electrode portion for operating the organic electroluminescent layer 126 does not need to be formed on the PCB substrate 110. This enables to increase a light-emitting area of the OELD device 100C. In addition, the first electrode 124 may be formed in the first region C of the PCB substrate 110, and the second electrode 128, which is connected to the second through electrode 118b, may extend over the first electrode 124. Accordingly, it is possible to reduce a distance between the first electrode 124 and the second electrode 128, and the OELD device 100C may be configured to have a shortened current path. As a result, the OELD device 100C can overcome the non-uniformity problem of display quality. Furthermore, the first conductive layer 116a, the first through electrode 116b and the second conductive layer 116c and the connection electrode 118 may be formed of metallic materials with a high thermal conductivity. As a result, the OELD device 100C can exhibit improved heat-dissipation efficiency without the unintended voltage drop phenomenon.

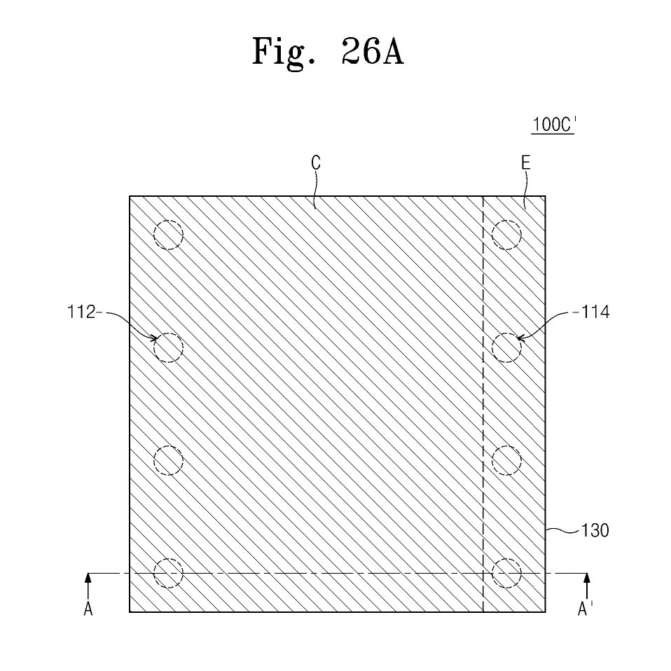

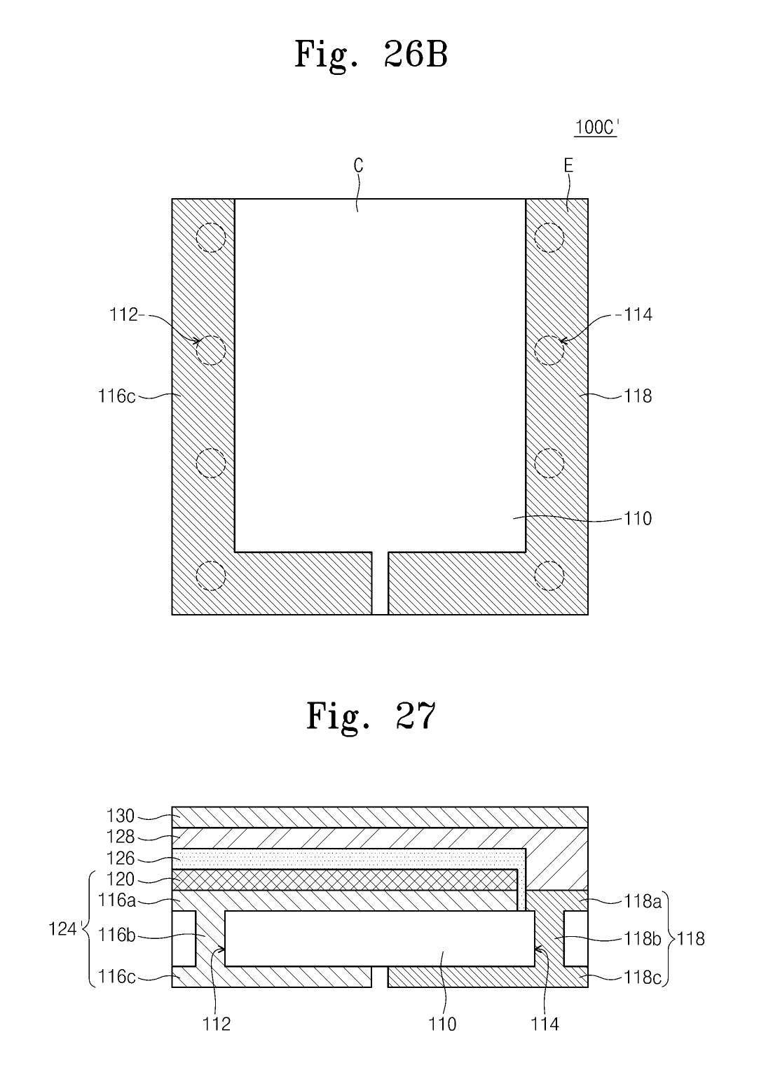

FIGS. 26A and 26B are top and bottom plan views of another embodiment of an OELD device with an inverted structure , and FIG. 27 is a sectional view taken along a dotted line A-A′ of FIG. 26A. For concise description, an element previously described with reference to FIGS. 25A and 25B may be identified by a similar or identical reference number without repeating an overlapping description thereof.

Referring to FIGS. 26A, 26B and 27, an OELD device 100C′ with the inverted structure may be provided. The OELD device 100C′ may include the PCB substrate 110, a first electrode 124′, the organic electroluminescent layer 126, the second electrode 128, and the connection electrode 118 electrically connected to the second electrode 128.

The first electrode 124′ may include the first conductive layer 116a, the first through electrode 116b, the second conductive layer 116c, and the reflective layer 120. The first electrode 124′ may serve as a cathode supplying electrons to the organic electroluminescent layer 126. In some embodiments, the second conductive layer 116c and the reflective layer 120 may contribute to improve heat-dissipation efficiency and reflectance of the OELD device 100C′ and to suppress an unintended voltage drop phenomenon. In other embodiments, the OELD device 100C′ may not include the second conductive layer 116c and the reflective layer 120.

The second electrode 128 may be formed of a transparent electrode having a higher work function than the first electrode 124′. In some embodiments, the second electrode 128 may be formed of an ITO layer or an IZO layer. In some embodiments, the second electrode 128 may serve as an anode supplying holes to the organic electroluminescent layer 126.

The connection electrode 118 may include the fourth conductive layer 118a, the second through electrode 118b, and the third conductive layer 118c. The third conductive layer 118c and the fourth conductive layer 118a may contribute to reduce an unintended voltage drop phenomenon. In some embodiments, the OELD device 100C′ may not include the third conductive layer 118c and/or the fourth conductive layer 118a.

In these embodiments, the first electrode 124′ and the second electrode 128 may be used as the cathode and the anode of the OELD device 100C′, respectively, and the first electrode 124′ may not include a transparent electrode provided on the reflective layer 120. Except for these points, the OELD device 100C′ may be the same as the OELD device 100C, which was described with reference to FIGS. 10A through 16A and 10B through 16B, in terms of materials and/or forming methods of elements thereof. Although the OELD device 100C of FIG. 25B may exhibit improved properties compared with the OELD device 100C′ of FIG. 27, the OELD device 100C′ of FIG. 27 may exhibit the substantially same properties as the OELD device 100C of FIG. 25B in terms of, for example, light-emitting area, a heat-dissipation efficiency, and the unintended voltage drop phenomenon.

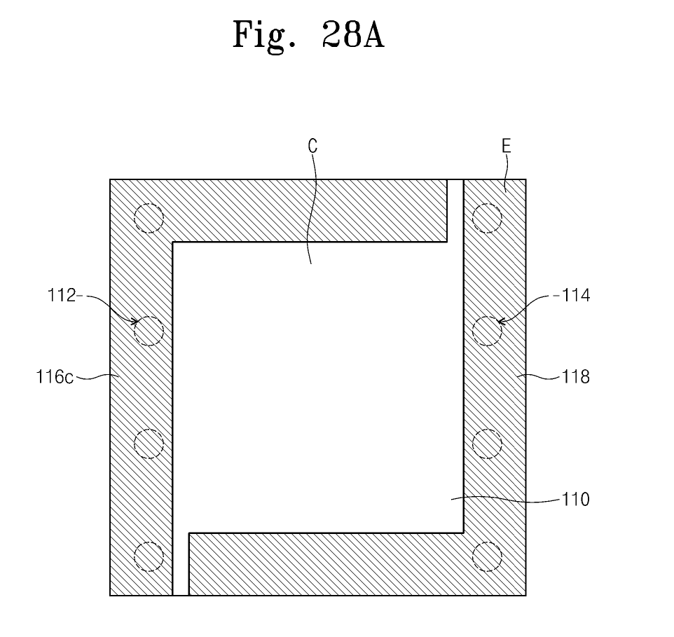

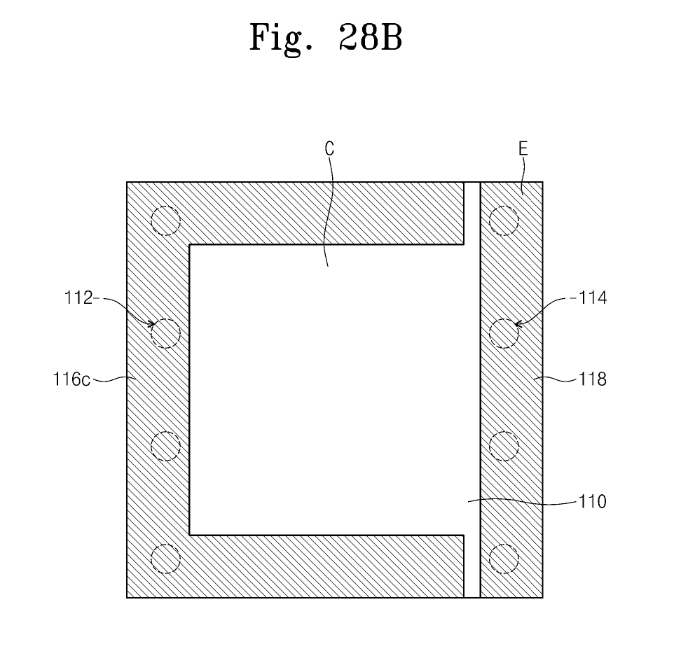

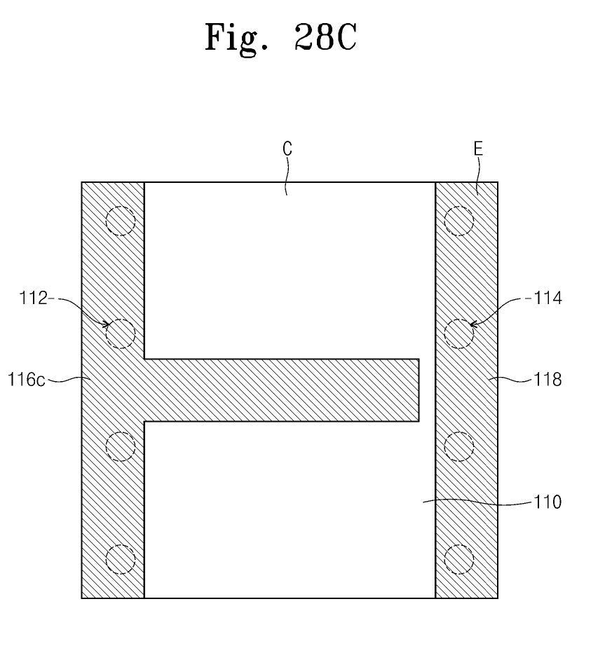

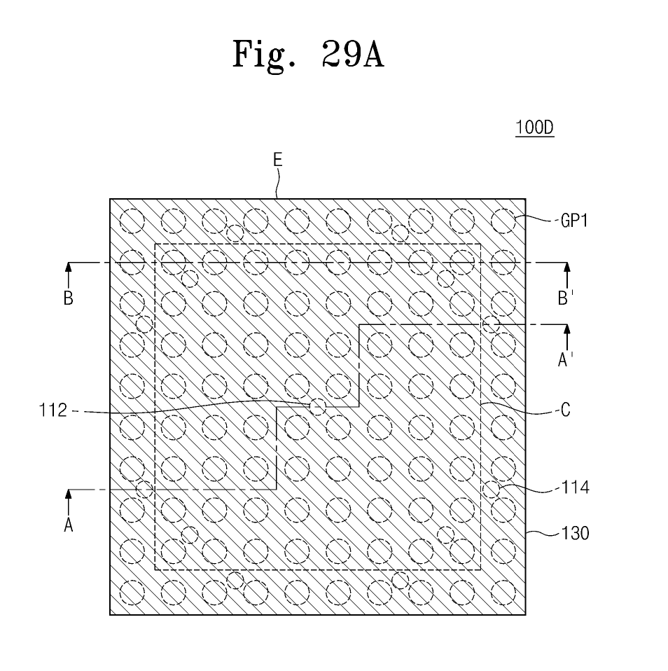

FIGS. 28A through 28C are plan views of modified embodiments of OELD devices with an inverted structure. For concise description, an element previously described with reference to FIG. 19A may be identified by a similar or identical reference number without repeating an overlapping description thereof.

The first conductive layer 116c, which is formed below the PCB substrate 110 in the first region C, may have one of various shapes. In some embodiments, the first conductive layer 116c may be shaped like one of the letters ‘L’, ‘U’, or ‘T’, as shown in FIG. 28A through 28C.

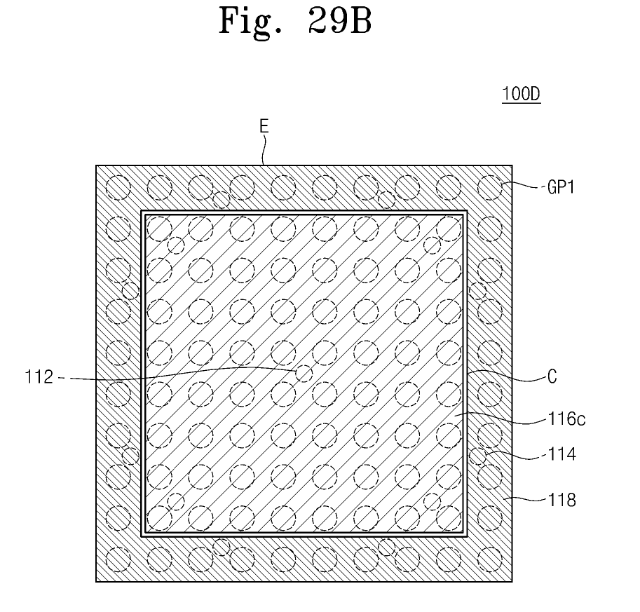

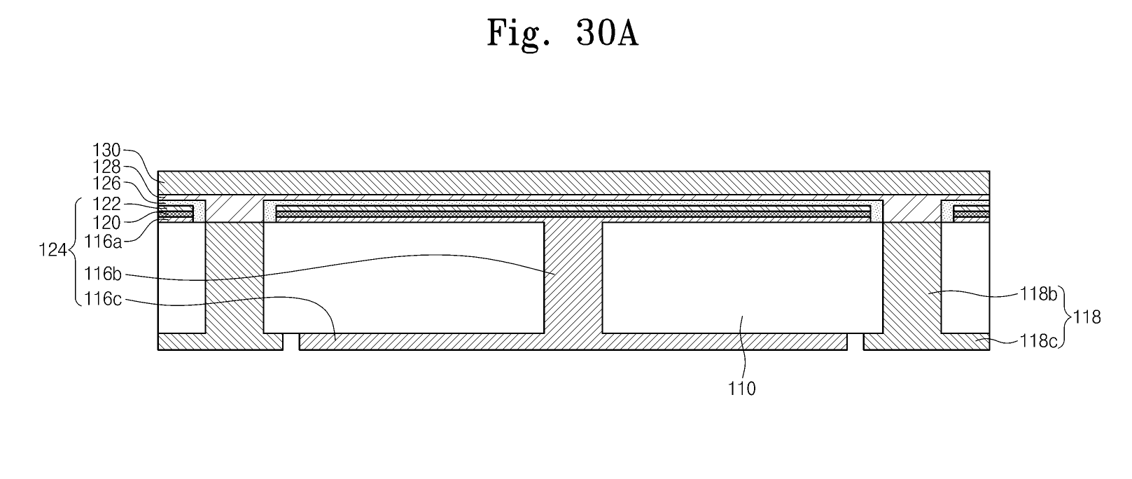

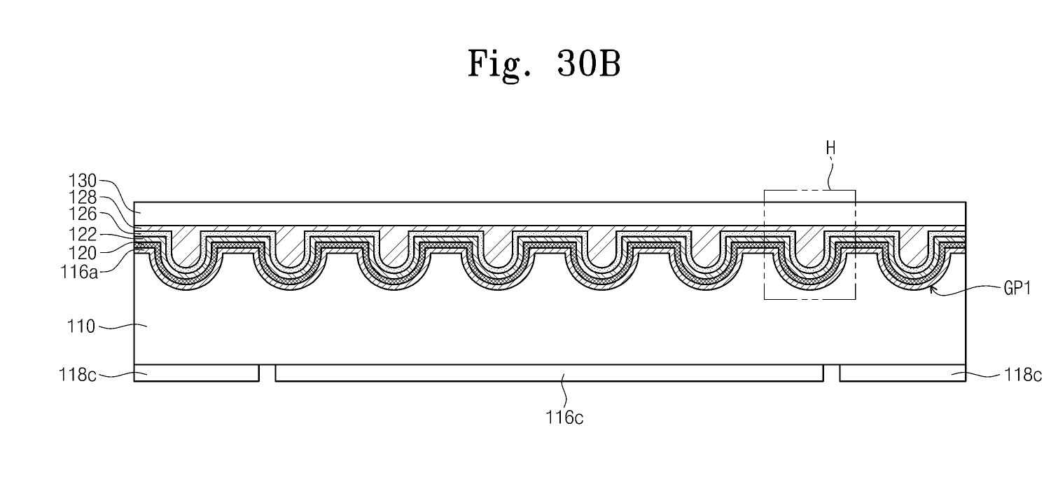

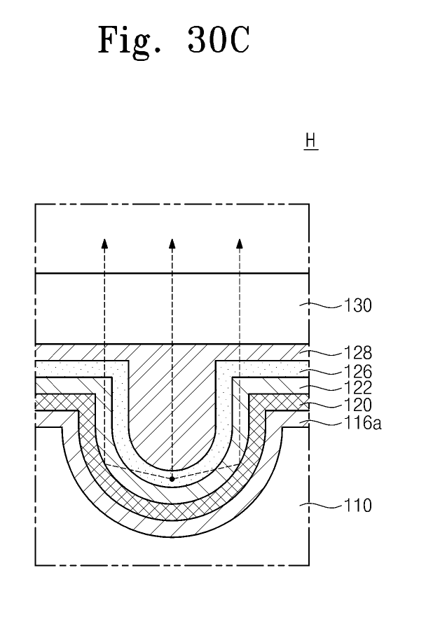

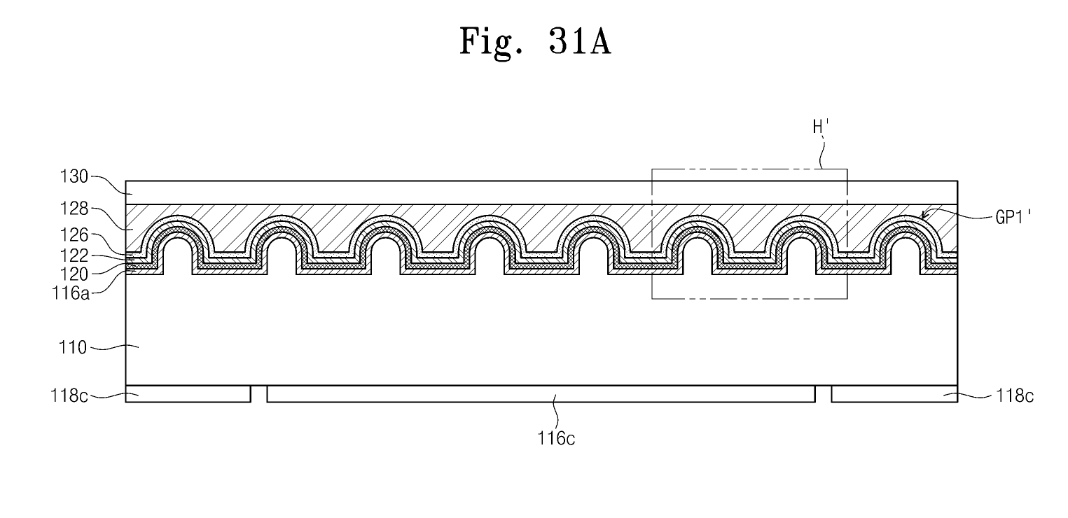

FIG. 29A and FIG. 29B are plan and bottom views illustrating another embodiment of an OELD device, FIG. 30A is a sectional view taken along line A-A′ line of FIG. 29A, FIG. 30B is a sectional view taken along line B-B′ line of FIG. 29A, and FIG. 30C is an enlarged view of region H of FIG. 30B. For concise description, a previously described element may be identified by a similar or identical reference number and an overlapping description thereof will not be repeated herein.

Referring to FIGS. 29A, 29B, 30A, 30B, and 30C, an OELD device 100D may include the PCB substrate 110, the first electrode 124, the organic electroluminescent layer 126, the second electrode 128, and the encapsulating layer 130.

The PCB substrate 110 may include the first region C including at least one first through hole 112 and the second region E including at least one second through hole 114. The second region E may be provided adjacent to an edge of the first region C to surround the first region C.

The first electrode 124 may be configured to supply holes or electrons to the organic electroluminescent layer 126. The first electrode 124 may include the first through electrode 116b, the first conductive layer 116a, the second conductive layer 116c, the reflective layer 120, and the transparent conductive layer 122.

The first through electrode 116b may be provided in the first through hole 112. The first conductive layer 116a may be provided on the PCB substrate 110 and be electrically connected to the first through electrode 116b. The second conductive layer 116c may be provided in the first region C below the PCB substrate 110 and be electrically connected to the first through electrode 116b. The reflective layer 120 may be disposed on the first conductive layer 116a, and the transparent conductive layer 122 may be disposed on the reflective layer 120.

The organic electroluminescent layer 126 may be disposed between the first electrode 124 and the second electrode 128 and may be configured to emit outward energy generated by the recombination of holes and electrons in the form of light. In other words, a light may be generated from the organic electroluminescent layer 126.

The second electrode 128 may be disposed on the organic electroluminescent layer 126 to supply electrons or holes to the organic electroluminescent layer 126.

In the embodiment of the OELD device 100D, at least one of the PCB substrate 110, the first conductive layer 116a, the reflective layer 120, and the transparent conductive layer 122 may be formed to realize a plurality of light extraction patterns GP1. In some embodiments, the light extraction patterns GP1 may be realized by all the PCB substrate 110, the first conductive layer 116a, the reflective layer 120, and the transparent conductive layer 122.

Each of the light extraction patterns GP1 may be realized using a recess formed in one of the PCB substrate 110, the first conductive layer 116a, the reflective layer 120, and the transparent conductive layer 122 and be formed to have a circular shape, from plan view.

In some example embodiments, the uppermost level of the light extraction patterns GP1 may be more adjacent to the bottom surface of the PCB substrate 110 than the lowermost level of the organic electroluminescent layer 126. By virtue of this recess structure of the light extraction patterns GP1, the light generated in the light extraction patterns GP1 may be reflected by the light extraction patterns GP1 and be emitted practically outward through the second electrode 128.

For the sake of simplicity, the description has referred to an example of the present embodiment in which the light extraction pattern GP1 is realized using all of the PCB substrate 110, the first conductive layer 116a, the reflective layer 120, and the transparent conductive layer 122, but other embodiments may not be limited thereto. For example, in other embodiments, the light extraction pattern GP1 may have one of structures configured to reflect a light generated therein toward the second electrode 128.

As described above, the light extraction patterns GP1 of the OELD device 100D may be configured to be able to reflect a light, which may not be initially oriented to the second electrode 128, toward the second electrode 128. As a result, light extraction efficiency of the OELD device 100D can be improved in the outward direction from the second electrode 128.

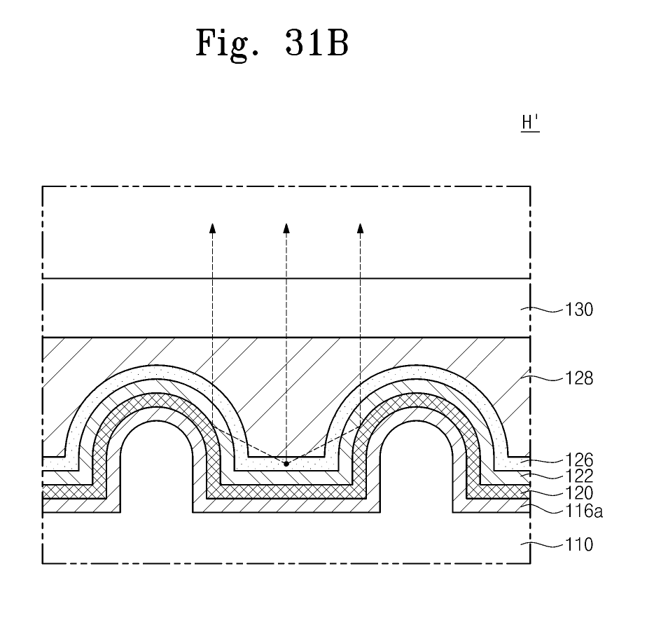

FIG. 31A is a sectional view illustrating a modified embodiment of the OELD device, and FIG. 31B is an enlarged view of region H′ of FIG. 31A. For concise description, an element previously described with reference to FIGS. 29A and 29B may be identified by a similar or identical reference number without repeating an overlapping description thereof.

Referring to FIG. 31A and FIG. 31B, an OELD device may include light extraction patterns GP1′, each of which may be formed to have a protruded structure.

In example embodiments, between adjacent light extraction patterns GP1′, the uppermost level of the light extraction pattern GP1′ may be higher than the lowermost level of the organic electroluminescent layer 126. Accordingly, a light generated between adjacent light extraction patterns GP1′ may be reflected by the protruding portions of the light extraction patterns GP 1′ and be emitted practically outward through the second electrode 128.

As described above, due to the presence of the light extraction pattern GP1′, the light extraction efficiency of the OELD device can be improved in the outward direction from the second electrode 128.

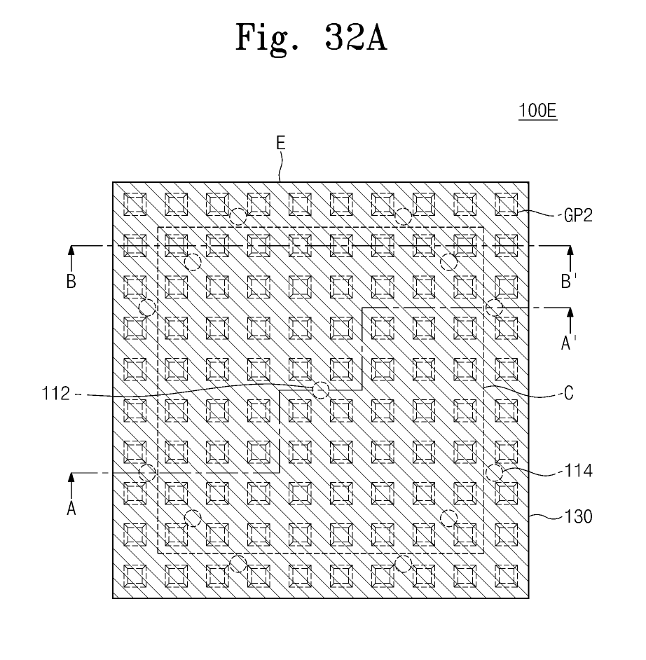

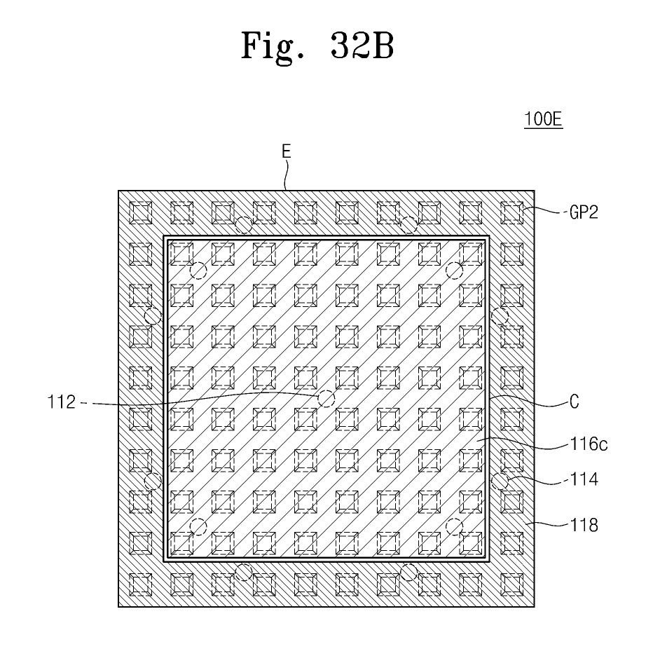

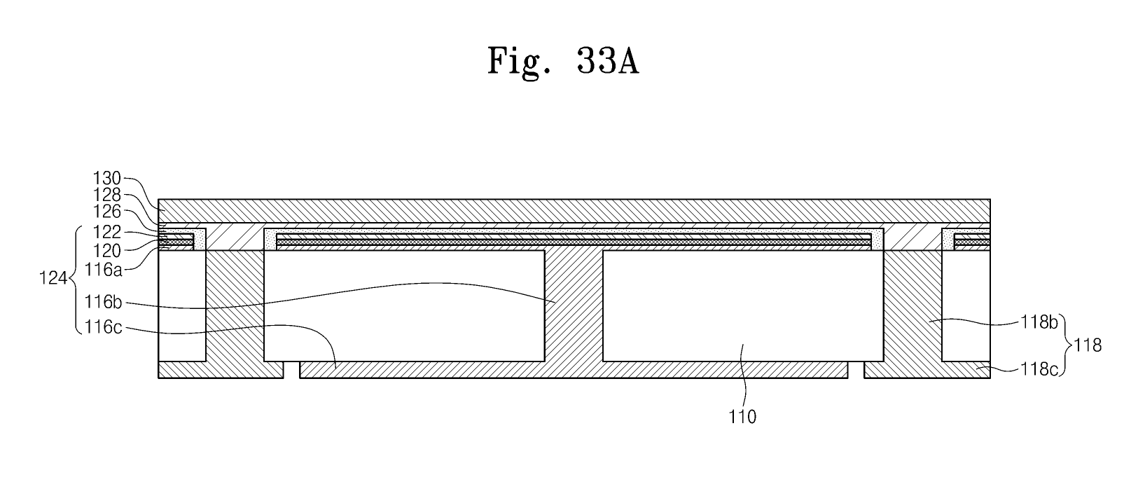

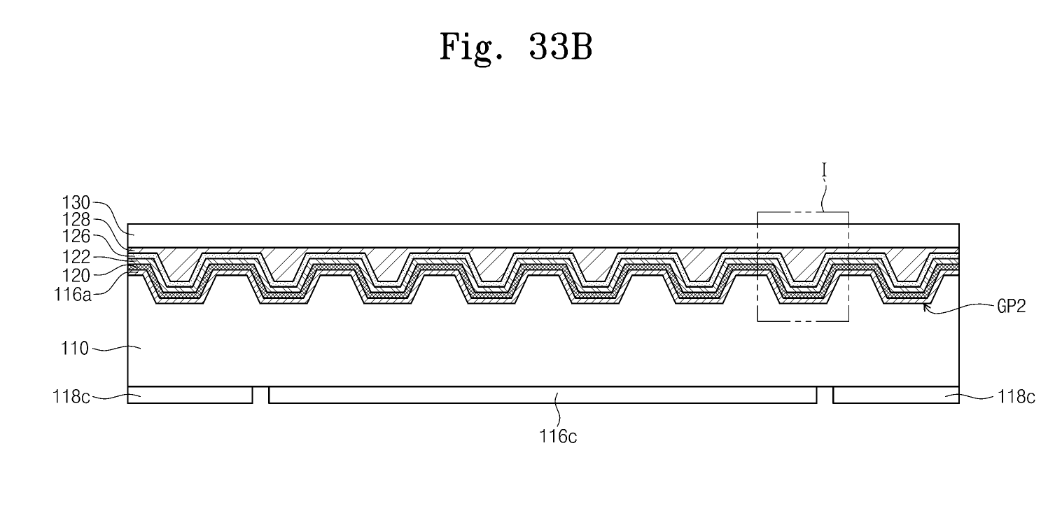

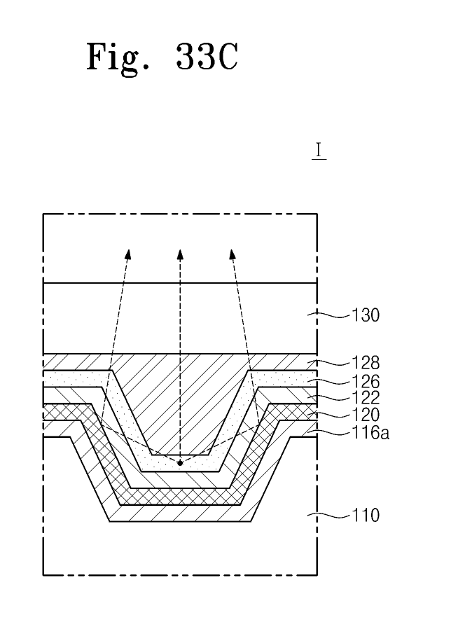

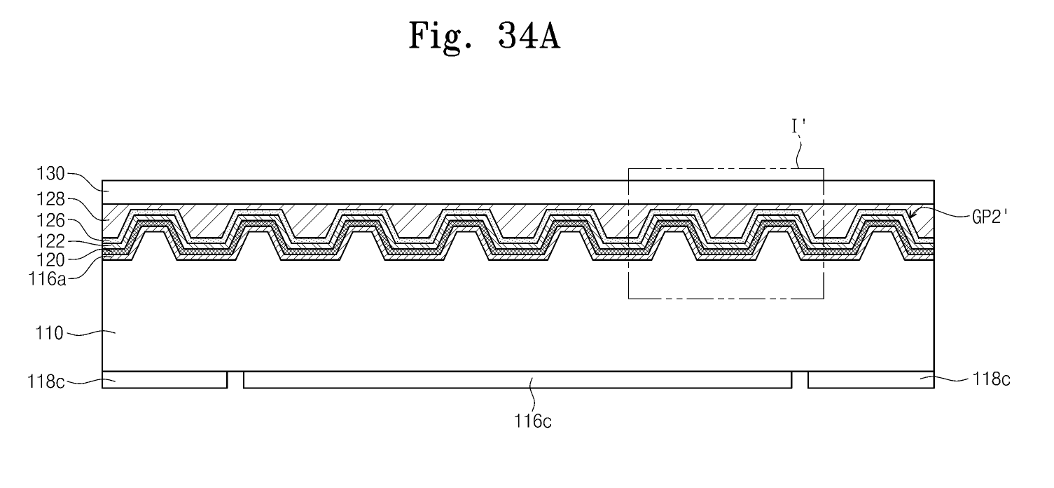

FIG. 32A and FIG. 32B are plan and bottom views illustrating another embodiment of an OELD device, FIG. 33A is a sectional view taken along line A-A′ of FIG. 32A, FIG. 33B is a sectional view taken along line B-B′ of FIG. 32A, and FIG. 33C is an enlarged view of region I of FIG. 32B. For concise description, a previously described element may be identified by a similar or identical reference number without repeating an overlapping description thereof.

Referring to FIG. 32A, FIG. 32B, FIG. 33A, FIG. 33B and FIG. 33C, an OELD device 100E may include the PCB substrate 110, the first electrode 124, the organic electroluminescent layer 126, the second electrode 128, and the encapsulating layer 130.

In the embodiment of the OELD device 100E, at least one of the PCB substrate 110, the first conductive layer 116a, the reflective layer 120, and the transparent conductive layer 122 may be formed to realize a plurality of light extraction patterns GP2, each of which may have a recessed structure from a sectional view and a polygonal shape from a plan view.

In example embodiments, the uppermost level of the light extraction patterns GP2 may be more adjacent to the bottom surface of the PCB substrate 110 than the lowermost level of the organic electroluminescent layer 126. By virtue of this recess structure of the light extraction patterns GP2, the light generated in the light extraction patterns GP2 may be reflected by the light extraction patterns GP2 and be emitted practically outward through the second electrode 128.

As described above, the light extraction patterns GP2 of the OELD device 100E may be configured to be able to reflect a light, which may not be initially oriented to the second electrode 128, toward the second electrode 128. As a result, the light extraction efficiency of the OELD device 100E can be improved in the outward direction from the second electrode 128.

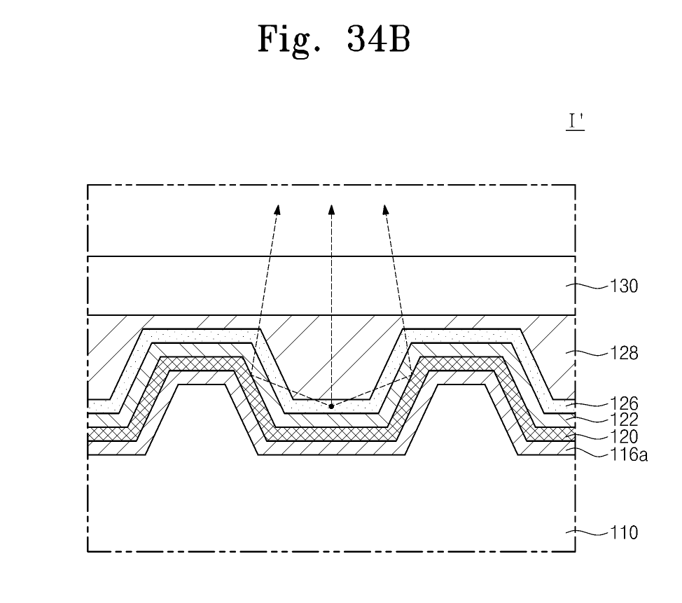

FIG. 34A is a sectional view illustrating a modified embodiment of the OELD device, and FIG. 34B is an enlarged view of region H′ of FIG. 34A. For concise description, an element previously described with reference to FIGS. 32A and 32B may be identified by a similar or identical reference number without repeating an overlapping description thereof.

Referring to FIG. 34A and FIG. 34B, an OELD device may include light extraction patterns GP2′, each of which may be formed to have a protruded structure.

In example embodiments, between adjacent light extraction patterns GP2′, the uppermost level of the light extraction pattern GP2′ may be higher than the lowermost level of the organic electroluminescent layer 126. Accordingly, a light generated between adjacent light extraction patterns GP2′ may be reflected by the protruding portions of the light extraction patterns GP2′ and be emitted practically outward through the second electrode 128.

As described above, due to the presence of the light extraction pattern GP2′, the light extraction efficiency of the OELD device can be improved in the outward direction from the second electrode 128.

According to certain embodiments, a PCB substrate may be used as a deposition substrate. As a result, an additional electrode portion for operating the organic electroluminescent layer does not need to be formed on the PCB substrate. This enables to increase a light-emitting area of the OELD device. In addition, a first electrode may be disposed in a first region of the PCB substrate and a second electrode connected to a though electrode, which is disposed in a second region of the PCB substrate, may be disposed on the PCB substrate. As a result, it is possible to reduce a distance between the first electrode and the second electrode, and the OELD device may be configured to have a shortened current path. Furthermore, the OELD device may have uniform display quality without an unintended voltage drop phenomenon. Moreover, due to the presence of conductive layers and through electrodes with a high thermal conductivity, the OELD device can exhibit improved heat-dissipation efficiency without an unintended voltage drop phenomenon.

While certain embodiments have been particularly shown and described, it will be understood by one of ordinary skill in the art that variations in form and detail may be made therein without departing from the spirit and scope of the attached claims.

What is claimed is:

1. An organic electroluminescent display (OELD) device, comprising:
a printed circuit board comprising a first region provided with at least one first through hole and a second region provided with at least one second through hole, the second region surrounding the first region;
a second through electrode disposed in the second through hole;
a first electrode comprising a first through electrode and a first conductive layer, the first through electrode being disposed in the first through hole, and the first conductive layer being disposed on the first through electrode and the printed circuit board, and being electrically separated from the second through electrode;
an organic electroluminescent layer disposed on the first electrode; and
a second electrode disposed on the organic electroluminescent layer and connected to the second through electrode.

2. The device of claim 1, wherein the second electrode is optically transparent.

3. The device of claim 1, wherein the first electrode further comprises a reflective layer disposed between the first conductive layer and the organic electroluminescent layer and is formed of a conductive material.

4. The device of claim 2, wherein the reflective layer comprises at least one of Ag, Ni or alloys thereof.

5. The device of claim 2, wherein the first electrode further comprises a transparent conductive layer interposed between the reflective layer and the organic electroluminescent layer.

6. The device of claim 4, wherein the transparent conductive layer comprises one of indium-tin-oxide (ITO), indium-zinc-oxide (IZO), aluminum zinc oxide (AZO), gallium doped zinc oxide (GZO), zinc tin oxide (ZTO), gallium tin oxide (GTO), and fluorine doped tin oxide (FTO).

7. The device of claim 4, wherein at least one of the printed circuit board, the first conductive layer, the reflective layer, and the transparent conductive layer is configured to form a plurality of light extraction patterns, and the light extraction patterns are configured to reflect a light generated from the organic electroluminescent layer toward the second electrode.

8. The device of claim 6, wherein the light extraction patterns have a recessed structure.

9. The device of claim 7, wherein an uppermost level of the light extraction pattern is more adjacent to a bottom surface of the printed circuit board than a lowermost level of the organic electroluminescent layer.

10. The device of claim 6, wherein the light extraction patterns have a protruding structure.

11. The device of claim 9, wherein an uppermost level of the light extraction pattern is higher than a lowermost level of the organic electroluminescent layer between adjacent light extraction patterns.

12. The device of claim 6, wherein each of the light extraction patterns is circular from a plan view.

13. The device of claim 6, wherein each of the light extraction patterns is polygonal from a plan view.

14. The device of claim 1, wherein the first electrode further comprises a second conductive layer disposed below the first through electrode and the printed circuit board.

15. The device of claim 13, further comprising a third conductive layer connected to the second through electrode and disposed along an edge of the printed circuit board.

16. The device of claim 14, wherein the third conductive layer is spaced apart from the second conductive layer and has a closed loop shape surrounding the second conductive layer.

17. The device of claim 14, wherein at least one of the first electrode, the second through electrode, and the third conductive layer comprises one of copper (Cu), gold (Au), and alloys thereof.

18. An organic electroluminescent display (OELD) device, comprising:
a printed circuit board comprising a first region provided with at least one first through hole and a second region provided with at least one second through hole, the first and second regions being adjacent to first and second edges of the printed circuit board, respectively;
a second through electrode disposed in the second through hole;
a first electrode comprising a first through electrode and a first conductive layer, the first through electrode being disposed in the first through hole, and the first conductive layer being disposed on the first through electrode and the printed circuit board, and being spaced apart from the second through electrode;
an organic electroluminescent layer disposed on the first electrode; and
a second electrode disposed on the organic electroluminescent layer and connected to the second through electrode.

19. The device of claim 18, wherein the first electrode further comprises a second conductive layer disposed below the first through electrode and the printed circuit board.

20. The device of claim 19, wherein the second conductive layer extends from the first edge of the printed circuit board to the second edge thereof adjacent to the first edge.

21. The device of claim 19, further comprising a third conductive layer disposed below the second through electrode and spaced apart from the second conductive layer, wherein the third conductive layer extends from the second edge of the printed circuit board to the first edge thereof adjacent to the second edge.

22. The device of claim 21, wherein each of the second and third conductive layers comprises an extension to have an ‘L’-shaped section, and the extensions of the second and third conductive layers are opposite to each other.

23. The device of claim 22, further comprising a fourth conductive layer disposed on the second through electrode, wherein the fourth conductive layer is spaced apart from the first conductive layer and disposed adjacent to the second edge of the printed circuit board.

24. The device of claim 21, wherein at least one of the first electrode, the second through electrode, and the third conductive layer comprises one of copper (Cu), gold (Au), and alloys thereof.

25. The device of claim 18, wherein the first electrode further comprises a reflective layer disposed between the first conductive layer and the organic electroluminescent layer and is formed of a conductive material.

26. The device of claim 25, wherein the reflective layer comprises at least one of Ag, Ni or alloys thereof.

27. The device of claim 25, wherein the first electrode further comprises a transparent conductive layer interposed between the reflective layer and the organic electroluminescent layer.

28. The device of claim 27, wherein the transparent conductive layer comprises one of indium-tin-oxide (ITO), indium-zinc-oxide (IZO), aluminum zinc oxide (AZO), gallium doped zinc oxide (GZO), zinc tin oxide (ZTO), gallium tin oxide (GTO), and fluorine doped tin oxide (FTO).

29. The device of claim 27, wherein at least one of the printed circuit board, the first conductive layer, the reflective layer, and the transparent conductive layer is configured to form a plurality of light extraction patterns, and the light extraction patterns are configured to reflect a light generated from the organic electroluminescent layer toward the second electrode.

30. The device of claim 29, wherein the light extraction patterns have a recessed structure.

31. The device of claim 30, wherein an uppermost level of the light extraction pattern is more adjacent to a bottom surface of the printed circuit board than a lowermost level of the organic electroluminescent layer.

32. The device of claim 29, wherein the light extraction patterns have a protruding structure.

33. The device of claim 32, wherein an uppermost level of the light extraction pattern is higher than a lowermost level of the organic electroluminescent layer between adjacent light extraction patterns.

34. The device of claim 29, wherein each of the light extraction patterns is circular from a plan view.

35. The device of claim 29, wherein each of the light extraction patterns is polygonal from a plan view.
